(19) United States
(12) Patent Application Publication
(10) Pub. No.: US 2010/0277164 A1
(43) Pub. Date: Nov. 4, 2010

(54) Method and apparatus for signal recovery

(75) Inventors: David Louis Tilbrook, New South Wales (AU); Graham Ross Daniels, New South Wales (AT); Florian Andreas Oppolzer, Werneck (DE); Marcel Bick, Manly (AT); Kyle Robert Blay, New South Wales (AT)

Correspondence Address: NIXON & VANDERHYE, PC, 901 NORTH GLEBE ROAD, 11TH FLOOR, ARLINGTON, VA, 22203, US

(73) Assignee: Commonwealth Scientific and Industrial Research Organisation, Campbell (AU)

(21) Appl. No.: 12/310,518

(22) PCT Filed: Sep. 3, 2007
(86) PCT No.: PCT/AU2007/001285

§ 371 Date: Feb. 27, 2009

(30) Foreign Application Priority Data
Sep. 1, 2006 (AU) 2006904801

(51) Int. Cl. G01R 33/02; G01R 23/00

(52) U.S. Cl. 324/244; 324/76.19

(57) ABSTRACT

Method and system for detecting magnetic contaminants in products (160). The product (160) is transported past magnetic sensors (170, 180) which return a first sensed signal S1 (172) and a second sensed signal S2 (182) being time-spaced received versions of the source signal produced by the product (160). From the sensed signals (172, 182) it is determined whether a magnetic contaminant has been detected. Gradiometry may be applied between the signals (172, 182). A so-called auto-cross-correlation comprising +/−(CC1+CC2−AC1−AC2) derived from the cross-correlation (CC1) of S1 with S2, the cross-correlation (CC2) of S2 with S1, the autocorrelation (AC1) of S1 and the autocorrelation (AC2) of S2, may be used to improve signal recovery from noise. The auto-cross-correlation may be applied in other applications.

### CROSS-REFERENCE TO RELATED APPLICATIONS

The present application claims priority from Australian Provisional Patent Application No 2006904801 filed on 1 Sep. 2006, the content of which is incorporated herein by reference.

### TECHNICAL FIELD

The present invention relates to sensing a signal by obtaining multiple time-spaced records of the signal.

### BACKGROUND OF THE INVENTION

There exist a wide range of situations in which it is desirable to sense a signal in the presence of noise, whether the signal is an acoustic signal, a voltage signal, an electromagnetic signal or other type of signal. In such applications a suitable sensor will output a received signal comprising both the signal and noise. From that received signal, it is desirable to be able to remove or minimise the noise and to improve extraction or recovery of the signal. In communications applications improved extraction of a signal in the presence of noise might enable increased channel capacity, while in detection applications improved extraction of a signal in the presence of noise is desirable to avoid a false negative response, or the like.

A detection application in which it is desirable to detect very small signals in a noisy environment, is in attempting to detect conductive and/or magnetic contaminants in consumer products. For example, one such contaminant which raises particular problems is broken stainless steel needles in meat products. Animals receive injections during their lifetime, and it occasionally happens that a portion of the needle breaks off and remains within the animal body. Hygiene requirements often necessitate that needles and other tools used throughout food and medicine production processes be made of stainless steel. However, stainless steel has an extremely weak magnetic signature, making it very difficult to detect stainless steel contaminants in consumer products, especially when a high volume detection process is needed. Failure to detect a contaminant in a product can be a considerable hazard to human health later on when the product is used or consumed.

Other magnetic contaminants which may be present in animal products can include fencing wire, buckshot, feed container parts, and the like. Contaminants can also occur in pharmaceuticals, cosmetics, and other products.

One class of detection system addressing the problem of contaminants in consumer products is the X-ray system. X-ray detection systems are expensive, generally costing in the hundreds of thousands of dollars, but can detect many kinds of contaminants and not only magnetic contaminants. X-ray detection systems capable of penetrating large products such as larger blocks of meat need increased X-ray power, increasing the cost and also increasing shielding requirements for the safety of people nearby. While there appears to be no scientifically observed negative effects upon a product subjected to x-ray detection, the use of X-ray detection on consumer products, and food in particular, nevertheless suffers from industry misgivings.

Another class of detection system involves use of SQUID sensors to detect contaminants having a magnetic signature. SQUID sensors possess very high sensitivity to B-field and can detect flux smaller than one flux quanta (˜2.07×10⁻¹⁵ Wb). SQUID magnetometers act as a flux to voltage transducer, while SQUID gradiometers act as a flux gradient to voltage transducer. SQUID systems are the most sensitive type of detection system, and are presently less expensive than x-ray systems.

One factor limiting the take up of SQUID-based systems is that the high sensitivity of SQUID sensors to noise imposes a need for proper magnetic shielding, which is difficult in high throughput applications. A second such factor is the need for sophisticated signal conditioning and processing to produce a reliable and stable system. Further, while a contaminant's magnetic field could be aligned in any direction, a SQUID magnetometer is sensitive in only one direction, such that the field of a stationary magnetic dipole aligned perpendicular to the sensitivity axis of a SQUID does not couple with and thus can not be detected by the SQUID. Also, it is necessary to cool the superconducting components to below their critical temperature (˜90K or less), leading to the need for regular re-supply of the cryogenic fluid, namely liquid nitrogen for high temperature superconductors or liquid helium for low temperature superconductors. Cryogenic fluids present a safety hazard, requiring trained technicians for handling.

Yet another class of detection system are flux gates, operation of which involves similar principles to SQUIDs, but with less sensitivity.

Another class of detection system involves use of electromagnetic induction (EMI) coils. While currently having a relatively low system cost in the tens of thousands of dollars, and being able to detect any conductive material, EMI systems can not perform detection of contaminants inside a metal container such as an aluminium foil container or aluminium can. EMI systems are also substantially less sensitive than SQUID systems and X-ray systems.

Any discussion of documents, acts, materials, devices, articles or the like which has been included in the present specification is solely for the purpose of providing a context for the present invention. It is not to be taken as an admission that any or all of these matters form part of the prior art base or were common general knowledge in the field relevant to the present invention as it existed before the priority date of each claim of this application.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### SUMMARY OF THE INVENTION

According to a first aspect the present invention provides a method of recovering a source signal in a noisy environment, comprising:
obtaining a first received signal (S1) and a second received signal (S2), S1 and S2 being time-spaced received versions of the source signal;
determining the cross-correlation (CC1) of S1 with S2;
determining the cross-correlation (CC2) of S2 with S1;
determining the autocorrelation (AC1) of S1;
determining the autocorrelation (AC2) of S2; and
calculating +/−(CC1+CC2−AC1−AC2).

According to a second aspect the present invention provides a device for recovering a source signal in a noisy environment, comprising:
at least one sensor for obtaining a first received signal (S1) and a second received signal (S2), S1 and S2 being time-spaced received versions of the source signal; and
a processor for determining the cross-correlation (CC1) of S1 with S2, for determining the cross-correlation (CC2) of S2 with S1; for determining the autocorrelation (AC1) of S1; for determining the autocorrelation (AC2) of S2; and for calculating +/−(CC1+CC2−AC1−AC2).

According to a third aspect the present invention provides a computer program for recovering a source signal in a noisy environment, comprising:
code for obtaining a first received signal (S1) and a second received signal (S2), S1 and S2 being time-spaced received versions of the source signal;
code for determining the cross-correlation (CC1) of S1 with S2;
code for determining the cross-correlation (CC2) of S2 with S1;
code for determining the autocorrelation (AC1) of S1;
code for determining the autocorrelation (AC2) of S2; and
code for calculating +/−(CC1+CC2−AC1−AC2).

According to a fourth aspect the present invention provides a computer program product comprising computer program code means to make a computer execute a procedure for recovering a source signal in a noisy environment, the computer program product comprising:
computer program code means for obtaining a first received signal (S1) and a second received signal (S2), S1 and S2 being time-spaced received versions of the source signal;
computer program code means for determining the cross-correlation (CC1) of S1 with S2;
computer program code means for determining the cross-correlation (CC2) of S2 with S1;
computer program code means for determining the autocorrelation (AC1) of S1;
computer program code means for determining the autocorrelation (AC2) of S2; and
computer program code means for calculating +/−(CC1+CC2−AC1−AC2).

The first to fourth aspects of the present invention recognise that while cross-correlations and autocorrelations of such received signals having both signal and noise components produce several and varied mixed product terms, the noise terms and mixed terms can be mathematically subtracted out by calculating either CC1+CC2−AC1−AC2 or −CC1−CC2+AC1+AC2, which differ only by a negative. The operation of +/−(CC1+CC2−AC1−AC2) is referred to herein as the auto-cross-correlation of first and second signals.

It is further noted that a mathematically equivalent way to reach this outcome is to build the auto correlation function of a gradiometer signal, where the gradiometer signal is produced by +/−(S1−S2), and such a technique is thus included within the scope of the present invention.

The spaced apart time may arise from physical spacing of two sensors, with the arrival time of the source signal at each sensor being distinct. For example, a subject producing a substantially constant source signal may pass the sensors at a known velocity.

Alternatively, the sensors may be positioned at differing distances away from the origin of the source signal, such that the arrival time of the signal at each sensor is distinct, by an amount which depends on the speed of propagation of the signal. A scaling factor may be applied to compensate for attenuation of the signal between the two sensors, and/or to account for differing sensitivities of the two sensors.

Alternatively, the time spacing between S1 and S2 may arise by way of repeated transmission or generation of the source signal.

To improve recovery of the source signal at times when the source signal is present, the first and second sensed signal may be processed at other times in the absence of the source signal to account for background noise conditions. Such processing preferably comprises:
determining a background autocorrelation (BAC1) of S1;
determining a background autocorrelation (BAC2) of S2;
determining a background cross-correlation (BCC1) of S1 with S2;
determining a background cross-correlation (BCC2) of S2 with S1;
subtracting BAC1, BAC2, BCC1, BCC2 from AC1, AC2, CC1, CC2, respectively, to produce corrected auto correlations and cross correlations CAC1, CAC2, CCC1, CCC2; and
calculating +/−(CCC1+CCC2−CAC1−CAC2).

Preferred embodiments of the first to fourth aspects of the present invention may implement linear regression in the time or frequency domain in order to determine coefficients which take into account mismatches between the first and second signals, such that noise in S1 and S2 is balanced by the coefficients before the auto-cross-correlation is calculated.

According to a fifth aspect the present invention provides a method for detecting a magnetic contaminant in a product, the method comprising:
transporting the product past a magnetic sensing device;
obtaining a first sensed signal and a second sensed signal as the product passes the magnetic sensing device, the first sensed signal and the second sensed signal being time-spaced received versions of the source signal produced by the product; and
determining from the first sensed signal and the second sensed signal whether a magnetic contaminant has been detected.

According to a sixth aspect the present invention provides a system for detecting a magnetic contaminant in a product, the system comprising:
a magnetic shield casing;
means for transporting the product within the casing;
a magnetic sensing device within and shielded by the casing, configured to sense the magnetic moment of a passing magnetic contaminant at spaced apart times to produce a first sensed signal and a second sensed signal; and
a processor for determining from the first sensed signal and the second sensed signal whether a magnetic contaminant has been detected.

According to a seventh aspect the present invention provides a computer program for detecting a magnetic contaminant in a product, the method comprising:
code for obtaining a first sensed signal and a second sensed signal as the product is transported past a magnetic sensing device, the first sensed signal and the second sensed signal being time-spaced received versions of the source signal produced by the product; and
code for determining from the first sensed signal and the second sensed signal whether a magnetic contaminant has been detected.

According to an eighth aspect the present invention provides a computer program product comprising computer program code means to make a computer execute a procedure for detecting a magnetic contaminant in a product, the computer program product comprising:
computer program code means for obtaining a first sensed signal and a second sensed signal as the product is transported past a magnetic sensing device, the first sensed signal and the second sensed signal being time-spaced received versions of the source signal produced by the product; and
computer program code means for determining from the first sensed signal and the second sensed signal whether a magnetic contaminant has been detected.

The fifth to eighth aspects of the invention thus recognise that, in magnetic detection applications, it is desirable to obtain two time-spaced received versions of the source signal to provide for improved signal extraction and noise reduction. For example, the method of the first aspect of the invention may be applied in processing of the first and second sensed signal obtained in accordance with the fifth to eighth aspects of the invention.

Embodiments of the invention may comprise two separate sensors positioned along the path of travel and separated by a baseline distance. In such embodiments, the path of travel of a product through the magnetic casing is preferably longer than the baseline distance by a sufficient amount that it can be assumed that noise and signal sources external of the magnetic casing are recorded by the two sensors at substantially the same time. Such an arrangement provides for gradiometric extraction of the contaminant signal. Thus, in embodiments of the fifth to eighth aspects of the invention, the first sensed signal and second sensed signal may be combined in a gradiometer configuration to improve a signal to noise ratio. In such embodiments, the time-spacing of the first sensed signal and the second sensed signal is preferably pre-determined or controlled so as to take a value which maximises efficacy of the gradiometer function. For example, an expected time of a minima in the first sensed signal may be chosen to coincide with an expected time of a maxima in the second sensed signal so as to maximise the gradiometric output at that time. The value of the time spacing may be varied during operation by altering the velocity at which the product is transported past the sensor(s). Alternatively, coincidence of a minima in the first sensed signal with a maxima in the second sensed signal may be effected by providing a suitable physical spacing between two separate sensors used to produce the first sensed signal and the second sensed signal.

Embodiments utilising gradiometry may further apply regression, for example in the time domain or frequency domain, in order to account for differing sensitivities or responses of distinct sensors.

Further embodiments may utilise both auto-cross-correlation and gradiometry to provide two screening processes.

The magnetic sensing device preferably comprises two separate spaced apart magnetic sensors positioned along a path of travel of the transported product such that the velocity of the product determines the time spacing between the time at which the first sensed signal is obtained and the time at which the second sensed signal is obtained. However, the sensing of the contaminant at spaced apart times may occur by use of a single sensor whereby the transporting means is arranged to transport the product past the sensor twice, at a known time spacing.

Embodiments of the fifth to eighth aspects of the invention may further provide a pre-magnetization device to pre-magnetize the contaminant.

The sensors may each comprise a magnetometer, a SQUID magnetometer, a SQUID gradiometer, a fluxgate, an induction coil or other magnetic sensor.

Where the or each sensor is a SQUID sensor, the product and contaminant may be enclosed within aluminium. This is possible due to the capability of a suitable SQUID sensor to detect a magnetic contaminant even when enclosed in aluminium foil or an aluminium can, because aluminium is non-ferromagnetic. The magnetic contaminant may comprise any substance having a magnetic moment detectable by the first and second magnetic sensors.

Embodiments of the fifth to eighth aspects of the present invention preferably utilise SQUID sensors, in recognition of the high sensitivity of such sensors to magnetic fields such as produced by stainless steel particles, which are the most common metal contaminant in the food industry.

The fifth to eighth aspects of the present invention recognise that when a magnetic dipole is moving relative to a SQUID sensor, such as being carried past the SQUID by a conveyor, then the dipole will couple with and be detectable by the SQUID in a majority of circumstances. When aligned along the z-axis (parallel to the sensitivity axis of the SQUID), the dipole will be detectable. When aligned along the x-axis (the direction of travel), the dipole will also be detectable, due to movement of the dipole along the x-axis. Notably, in the latter circumstance, when the moving dipole is immediately below the SQUID sensor it's field does not couple with the SQUID and the SQUID gives a zero output. However, before and after this position, the dipole will couple with the SQUID and the SQUID will produce an anti-symmetric output. Thus, movement of products relative to the sensors improves both throughput and accuracy.

To enable detection of dipoles aligned along the y-axis, pre-magnetization may be applied to re-align dipoles to a detectable orientation. Additionally or alternatively, the sensor system may be made sensitive to the y-axis, by providing a second pair of SQUID sensors sensitive to dipoles aligned along the y-axis. In such arrangements, one or both of the output of the first SQUID pair and the output of the second SQUID pair may indicate detection of a passing contaminant, regardless of dipole orientation.

In yet another embodiment, the system may be made sensitive to the y-axis by providing only two sensors, each of which are sensitive to magnetic fields of differing orientation. One such type of sensor is set out in International Patent Publication No. WO 2004/015788, the content of which is incorporated herein by reference.

Upon detection of external dynamic noise, such as an irregular movement of a nearby ferromagnetic object, preferred embodiments may determine a linear fit of a cross correlation, to be deducted from the dynamic-noise affected sensed signals.

Preferred embodiments of the fifth to eighth aspects of the invention further comprise a means to determine when a product is passing the sensors. The means may comprise a light barrier across an entrance to the magnetic casing, such that a product entering the casing interrupts the light barrier, and such that a time at which that product is passing the sensors can be determined from the velocity at which the product is transported. Such knowledge enables an accurate expectation of a time at which a contaminant may induce a signal in the sensors.

Embodiments in which it is known when a product is passing the sensors preferably further provide for a first noise measurement and a second noise measurement to be obtained from the or each sensor when no product is passing, for example the first noise measurement may be obtained before the product passes the sensor and the second noise signal may be obtained after the product passes the sensor. In such embodiments, a cross correlation of the first and second noise measurements is preferably obtained. Such embodiments recognise that the cross-correlation function is phase independent and that, even though the first and second signals sensed from a product may be obtained at an earlier or later time, the cross-correlation of the noise measurement may be subtracted from the cross-correlation of the first and second signals to reduce the noise level and improve signal extraction.

The transport means preferably comprises a non-magnetic conveyor belt, driven by a motor external to the magnetic casing. The motor is preferably formed of minimal or no magnetic components. Alternatively the transport means may comprise a slide positioned at an angle such that gravity moves the product along the slide.

In embodiments where there can be some foreknowledge of an expected signal profile produced by a contaminant, a cross-correlation is preferably determined of one or both of the sensed signals with an expected sensed signal profile. Additionally or alternatively, the profile may be an expected cross-correlation profile, against which the cross-correlation of the first and second sensed signals may itself be cross-correlated. A plurality of such expected profiles, differing in a manner corresponding to factors such as varying dipole orientation, varying position of the contaminant laterally of the path of travel, contaminant distance from the sensor, and contaminant size, may be stored and each be cross correlated with the or each sensed signal. Thus, in addition to detecting the presence of a contaminant, identifying a profile which when cross correlated with a sensed signal or with the cross-correlation of the first and second sensed signals produces a maximal outcome may further convey information about the size, orientation and/or position of the contaminant. Such foreknowledge may be improved in embodiments which apply pre-magnetisation so as to align magnetic contaminants in a known direction, such as along the x-axis (the direction of travel).

In the fifth to eighth aspects of the invention, signal components of the sensed signals may be in a frequency band related to the velocity of the contaminant relative to the sensors. Thus, in preferred embodiments of the fifth to eighth aspects of the invention, band pass or low pass filtering is applied to the sensed signal obtained by the or each sensor in order to retain the signal components in the frequency band of interest, while attenuating signal components in other frequency bands. Such filtering is preferably high order filtering, for example 8th order or higher.

### BRIEF DESCRIPTION OF THE DRAWINGS

Examples of the invention will now be described with reference to the accompanying drawings, in which:

FIG. 1 is a photograph of a SQUID-based metal detector system prototype in accordance with an embodiment of the present invention;

FIG. 2A is a schematic of the system of FIG. 1;

FIGS. 2B to 2E illustrate coupling of a moving dipole aligned along the x-axis with a z-axis sensitive sensor;

FIGS. 2F to 2I illustrate coupling of a moving dipole aligned along the z-axis with a z-axis sensitive sensor;

FIG. 3 is a schematic of the cooled components of the two-SQUID magnetic sensor device of the system of FIG. 1;

FIG. 4 is a circuit schematic for outputting the sensed signals obtained by the two SQUIDs in the system of FIG. 1;

FIG. 5 illustrates a signal processing path for implementing a two-SQUID gradiometer;

FIG. 6 illustrates a signal processing path for implementing a two-SQUID gradiometer with regression in the time domain applied by factor α;

FIG. 7 illustrates a signal processing path for implementing a two-SQUID gradiometer with regression in the frequency domain applied by transfer function H(ω);

FIG. 8 illustrates the two SQUID signals produced by a passing sample;

FIG. 9 is a plot of amplitude vs. time for the normalised SQUID signals from FIG. 8, illustrating a time delay Δt between the two signals;

FIG. 10 is a plot of the cross-correlation of the two SQUID signals from FIG. 9, illustrating the presence of a maxima at time Δt;

FIG. 11 illustrates the value of lowpass filtering the signal of each SQUID in the system of FIG. 2;

FIG. 12 further illustrates the value of lowpass filtering the signal of each SQUID in the system of FIG. 2;

FIG. 13 illustrates the two SQUID signals, the gradiometer output, and the cross-correlation of the two SQUID signals, when a non-premagnetised 15 mm stainless steel wire was passed through the system of FIG. 2;

FIG. 14 is a plot of the two SQUID signals and the gradiometer signal obtained when a pre-magnetised stainless steel needle was passed through the system of FIG. 2, illustrating the larger peak value of the gradiometer signal;

FIG. 15 is a plot of the cross correlation of the two SQUID signals shown in FIG. 2;

FIG. 16 illustrates the constant time at which a maxima arises in the cross correlation of the two SQUID signals, when samples of varying size and orientation were passed through the system of FIG. 2;

FIG. 17 illustrates the two SQUID signals, the gradiometer output, and the cross-correlation of the two SQUID signals, when a ferrous sample of 1.5 mm diameter was passed through the system of FIG. 2;

FIGS. 18A and 18B illustrate the retrieval of a noise-only cross-correlation of the signals from the two SQUIDs from before and after the sample passes, and the subtraction of the noise-only cross-correlation from the signal+noise cross-correlation to improve sensitivity;

FIGS. 19A and 19B illustrate subtraction of the noise-only cross-correlation from the signal+noise cross-correlation where the signal cross-correlation is larger and smaller, respectively, in peak amplitude than the noise-only cross-correlation;

FIG. 20 is four plots of, respectively, first and second SQUID signals produced by a passing magnetic dipole, a zero noise signal, the cross correlation of the first and second SQUID signals, and the cross-minus-auto correlation function of the two signals which is equivalent to the auto-correlation of the first and second SQUID signals;

FIG. 21 is four plots of, respectively, first and second SQUID signals produced by a passing magnetic dipole in the presence of noise, a non-zero noise signal, the cross correlation of the first and second SQUID signals, and the auto-cross correlation of the first and second SQUID signals;

FIG. 22 is four plots of, respectively, identical first and second SQUID signals produced in the presence of noise and in the absence of any passing magnetic dipole, a non-zero noise signal, the cross correlation of the first and second SQUID signals, and the auto-cross correlation of the first and second SQUID signals;

FIG. 23 is four plots of, respectively, identical first and second SQUID signals produced in the presence of complex noise and in the absence of any passing magnetic dipole, a non-zero complex noise signal, the cross correlation of the first and second SQUID signals, and the auto-cross correlation of the first and second SQUID signals;

FIG. 24 is four plots of, respectively, first and second SQUID signals produced by a passing magnetic dipole in the presence of complex noise, a non-zero complex noise signal, the cross correlation of the first and second SQUID signals, and the auto-cross correlation of the first and second SQUID signals;

FIG. 25 columns 1 and 2 compare sub-plots of FIG. 24 to corresponding sub-plots of FIG. 23, while column 3 compares a sub-plot of FIG. 21 to a corresponding sub-plot of FIG. 22;

FIG. 26 illustrates a circumstance in which a large background signal may be detected by the two SQUIDs;

FIG. 27 illustrates the outputs signals of the two SQUIDs and the gradiometer under the circumstances shown in FIG. 26;

FIG. 28 illustrates the cross correlation of the two SQUID signals shown in FIG. 27, and a linear fit;

FIG. 29 illustrates an extracted cross-correlation approximation obtained by subtracting the linear fit of FIG. 28 from the cross-correlation of FIG. 28;

FIG. 30 illustrates the use of adaptive filtering based on the cross-correlation output;

FIG. 31 illustrates a simulation of a signal of two magnetic dipoles passing a magnetometer, recordings obtained by two spaced apart magnetometers in the presence of noise, and a gradiometer signal derived from the two gradiometers;

FIG. 32 illustrates the inverse auto correlation of the gradiometer signal of FIG. 31;

FIGS. 33a and 33b illustrate the peak size of a noise-only correlation and a contaminant signal autocorrelation, respectively; and

FIGS. 34a and 34b illustrate the waveform of a noise-only signal and the waveform of a contaminant signal, respectively.

### DESCRIPTION OF THE PREFERRED EMBODIMENTS

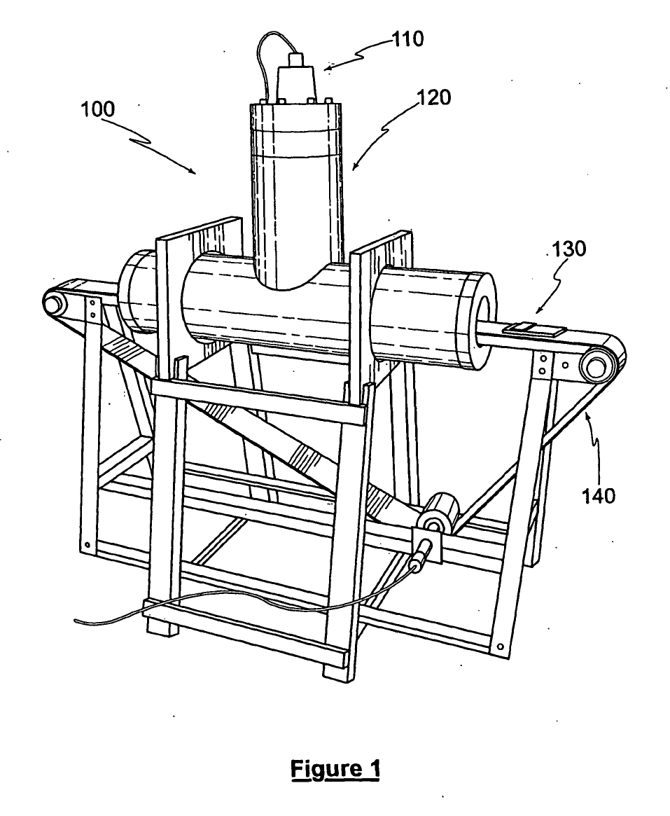

FIG. 1 is a photograph of a SQUID-based metal detector system prototype 100 in accordance with an embodiment of the present invention. A vacuum dewar 110 is located inside a three layer μ-metal shield 120, which achieves a shielding factor around 1000. However, the ends of the magnetic μ-metal casing are permanently open to allow through travel of a product 130 upon a conveyor belt 140. The upright cylinder of the metal shield 120 contains the dewar 110 which can be a vacuum dewar or a dewar filled with liquid nitrogen.

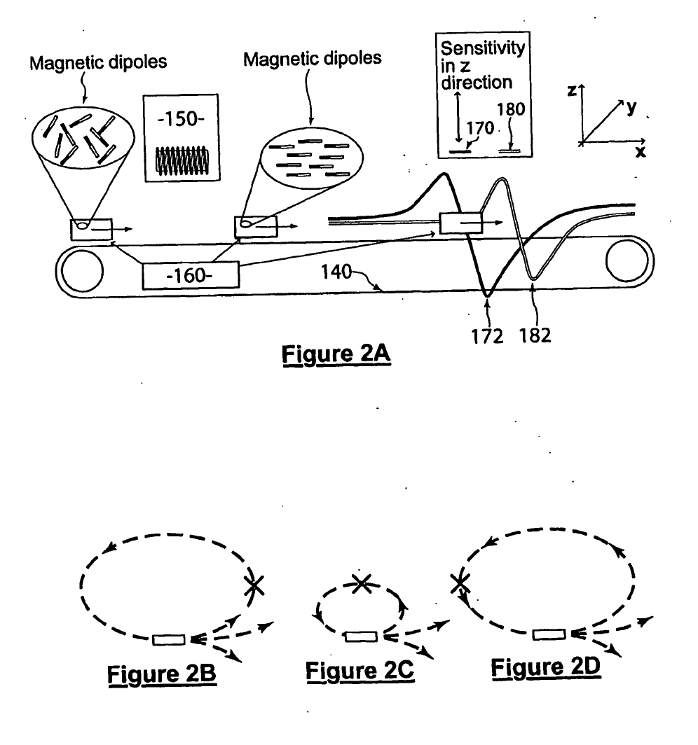

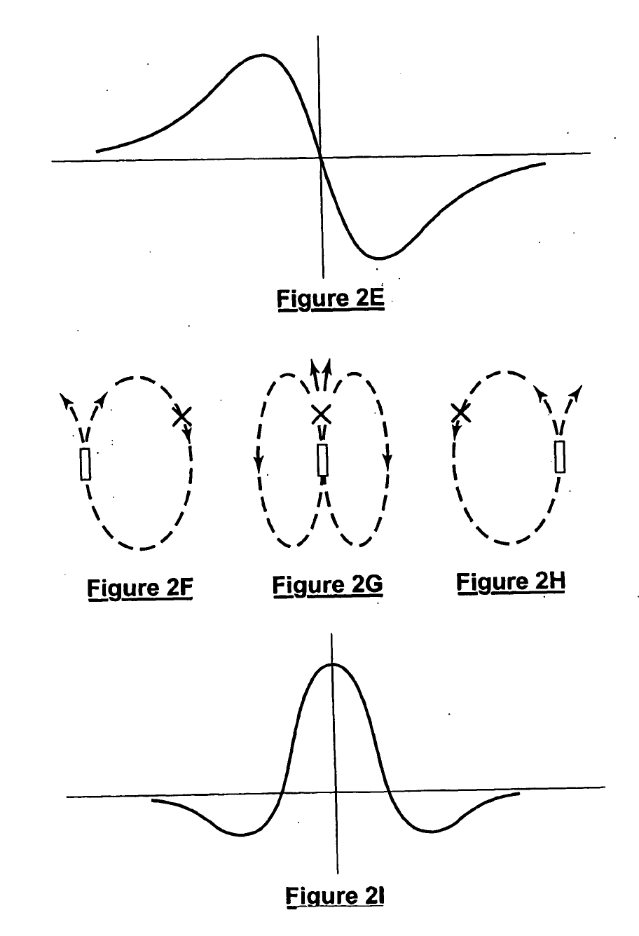

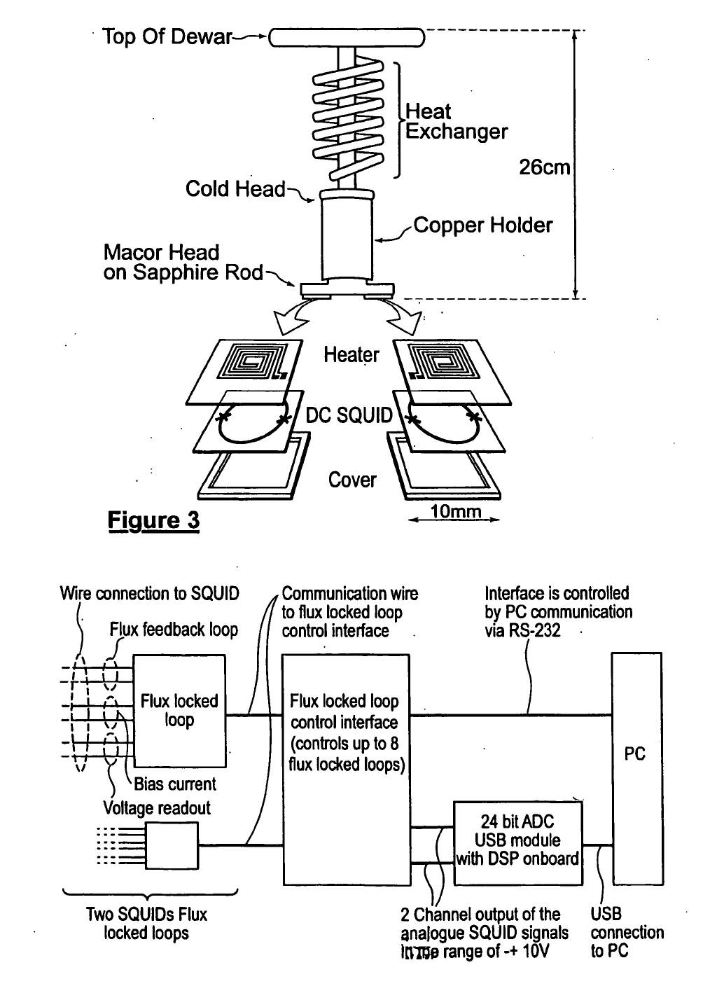

FIG. 2A is a schematic of the system 100 for sample recording. FIG. 2A shows the progression of a single product 160 containing a magnetic contaminant through the system 100, and how the magnetic contaminant is recorded. Prior to entry to the casing, the sample 160 is pre-magnetized in the x direction by pre-magnetizer 150, which increases the x-axis alignment of dipoles carried by the contaminant. The conveyor belt 140 then transports the sample 160 through the casing 120 with a substantially constant speed. This carries the sample 160 first past one SQUID magnetometer 170, and then past a second SQUID magnetometer 180. The SQUIDs 170, 180 are arranged in such way that they are sensitive to B field in the z-direction.

In the simplified case of a magnetic dipole, the shape of the signal produced as the dipole passes a magnetic detector will depend on the dipole orientation. The shape of signals 172, 182 shown in FIG. 2A are produced by a moving dipole lying parallel to the x-axis (direction of travel), where the sensitivity axis of the SQUID sensor is in the z-direction, perpendicular to the direction of travel. This signal shape is explained with reference to FIGS. 2B to 2E, which illustrate coupling of a moving dipole aligned along the x-axis with a z-axis sensitive sensor (denoted by X). As the dipole approaches the sensor, it's field threads through the sensor in the positive z-direction and thus can be detected by the sensor. When directly below the sensor, the net flux of the dipole's field threading through the sensor is zero, leading to zero sensor output in this position (at the origin in FIG. 2E). As the dipole moves away from the sensor, it's field threads through the sensor in the negative z-direction and thus can be detected by the sensor. Thus, this configuration leads to the anti-symmetric signal shape shown in FIGS. 2A and 2E.

By contrast, FIGS. 2F to 2I illustrate coupling of a moving dipole aligned along the z-axis with a z-axis sensitive sensor. The dipole's field threads the sensor weakly in the negative z-direction when at a distance (FIGS. 2F and 2H), and threads the sensor most strongly in the positive z-direction when directly below the sensor (FIG. 2G), leading to the symmetric shape of the sensor output signal shown in FIG. 2I.

Notably, a dipole aligned in the y-direction will always have zero net flux threading the sensor and thus be invisible in the arrangement of FIG. 2A, which is one reason why pre-magnetization 150 is applied. It is noted that alternative embodiments may utilise sensors which are operable to detect magnetic fields of varying orientation, configured to detect fields in both the x- and y-directions. One such detector could be as set out in WO 2004/015788.

In the embodiments discussed herein, pre-magnetization in the x-direction is chosen because, for a given dipole, the peak-to-peak amplitude of the signal shown in FIG. 2E is greater than the peak-to-peak amplitude of the signal shown in FIG. 2I. However, alternative embodiments of the present invention may apply pre-magnetization in a direction other than along the x-axis.

Yttrium barium copper oxide, YBa₂Cu₃O₇ (YBCO), a high temperature superconductor having a critical temperature of T_{c}=90K, is used for the DC-SQUIDs 170, 180. Thus, the SQUIDs 170, 180 used in system 100 must be operated at a temperature below 90 Kelvin, necessitating a cooling system. While liquid nitrogen having a boiling point around 77K is often used for SQUID applications, an alternative was chosen for this embodiment to improve usability and ease of maintenance of system 100 within a factory environment or production process. Accordingly, to avoid periodic refilling of the dewar 110 with liquid nitrogen, the present embodiment uses a Joule-Thomson cryocooler operating at about 70 K, and thus provides a system requiring reduced maintenance and reduced need for trained technicians to handle cryofluids.

A schematic of the vacuum dewar 110 internal assembly is shown in FIG. 3. The vacuum dewar 110 contains the Joule-Thomson cryocooler cold head with the two SQUIDs, the temperature diodes and the heater. As shown in FIG. 3, the two magnetometers 170, 180 are mounted in planar configuration on a macor holder which is connected to the cold head of the cryocooler. The two SQUIDs are separated by a baseline of 50 mm, along the conveyor belt. Providing two magnetometers 170, 180 in this manner enables both software gradiometry and cross correlation to be performed upon the magnetometer outputs, as discussed in more detail in the following.

The system 100 thus exploits highly sensitive SQUID magnetometers to implement a magnetic contaminant detector for food and safety applications. A particular strength of this system is the ability to detect stainless steel, the most common contaminant in the food industry, in contrast to the relative insensitivity of EMI coils in detecting stainless steel. Further, by utilising a magnetometer as the sensor, the system 100 can ‘see through’ aluminium foil, which is conductive but not ferromagnetic. This is in contrast to EMI systems which induce current in aluminium and thus can not effectively see through aluminium. The ability to detect contaminants in products wrapped in aluminium is particularly advantageous as aluminium is a common packaging material, particularly in the food industry.

Not only does the system 100 provide a means by which stainless steel may be detected, it is capable of sensing other types of magnetic contaminant which might have found a way into the product during the production process. A contaminant can be detected by system 100 provided it has a detectable magnetic moment.

FIG. 4 is a circuit schematic for outputting the sensed signals obtained by the SQUIDs 170, 180 in the system of FIG. 1. These SQUID electronics, including a flux locked loop are located on top of the vacuum dewar 110. Operation of a flux locked loop is explained, for example, in U.S. Pat. No. 5,635,834, the contents of which are incorporated herein by reference. Two separate sets of electronics are provided, one set for each SQUID 170, 180, the electronics being controlled by a control interface. This interface produces an analogue output for each SQUID sensor. Each channel of data is 24 bit A/D converted and further processed with signal processing software on a personal computer (PC), which in other embodiments could be a dedicated processor or central server. The SQUID electronics control interface is controlled by the PC and communicates with an RS 232 serial port.

The magnetic contaminant detector 100 is intended to be operated in situations such as a factory environment as part of a production process, and accordingly needs to function in the presence of a noisy environment and unwanted external signals. Processing of the output signals of the SQUID sensors should include a detection algorithm which is stable and resistant to false responses, whether a false positive response or a false negative response.

The present embodiment combines two separate signal processing approaches to extracting the contaminant signal of interest in the presence of such noise. Both approaches are based on the same (ideal) assumption that, due to the large size of the magnetic shielding 120 and the short 50 mm baseline between the two SQUIDs 170, 180, external noise and signals from distant sources are recorded by both SQUIDs with the same phase and amplitude at the same time. As a contaminant magnetic particle passes substantially more closely to the two SQUIDs 170, 180 than any external magnetic source, it is recorded with a gradient between the two SQUIDs at a particular time. As shown in FIG. 2A, the waveforms 172, 182 measured from a sample have substantially the same shape, but are separated by a time delay defined by the baseline separation of the SQUIDs 170, 180 and the conveyor belt speed. Waveforms 172 and 182 may have differing amplitude and/or spectral content depending upon the sensitivity and spectral response of each sensor.

Accordingly, the first signal processing approach utilised in the present embodiment is based on the recognition that, while each of the SQUIDs 170, 180 is operated as a magnetometer, they can be combined to form a first-order gradiometer. A software gradiometer is implemented by calculating the difference of the two SQUID magnetometer signals 172, 182. Due to the subtraction, common mode noise is minimised and the first order gradient is measured.

The software gradiometer of the system 100 can be adapted to different noise amplitudes and different spectral content of noise by multiplying one of signals 172, 182 by a constant factor so as to apply regression in the time domain, or by a transfer function so as to apply regression in the frequency domain. The constant factor and/or transfer function can be determined during a calibrating process which evaluates the noise environment and sensor responses, as discussed further in the following.

The second signal processing approach to noise reduction and signal extraction in the present embodiment is to build the cross correlation of the two magnetometer signals 172, 182. Because of the known time delay between the two magnetometer signals, the shape of the cross correlation function and the position of its maximum are predictable. The cross correlation maximum is a maximum relative to a noise environment cross correlation function shape. The cross correlation works to reduce any internal or external noise which is not correlated, which is simultaneously recorded with both SQUIDs.

Both signal processing approaches are operated in parallel in the present embodiment, to provide a more precise and reliable system. To improve the immunity to noise sources even further, high-order digital filters are implemented to reduce the spectral content to the band of interest, as discussed further in the following.

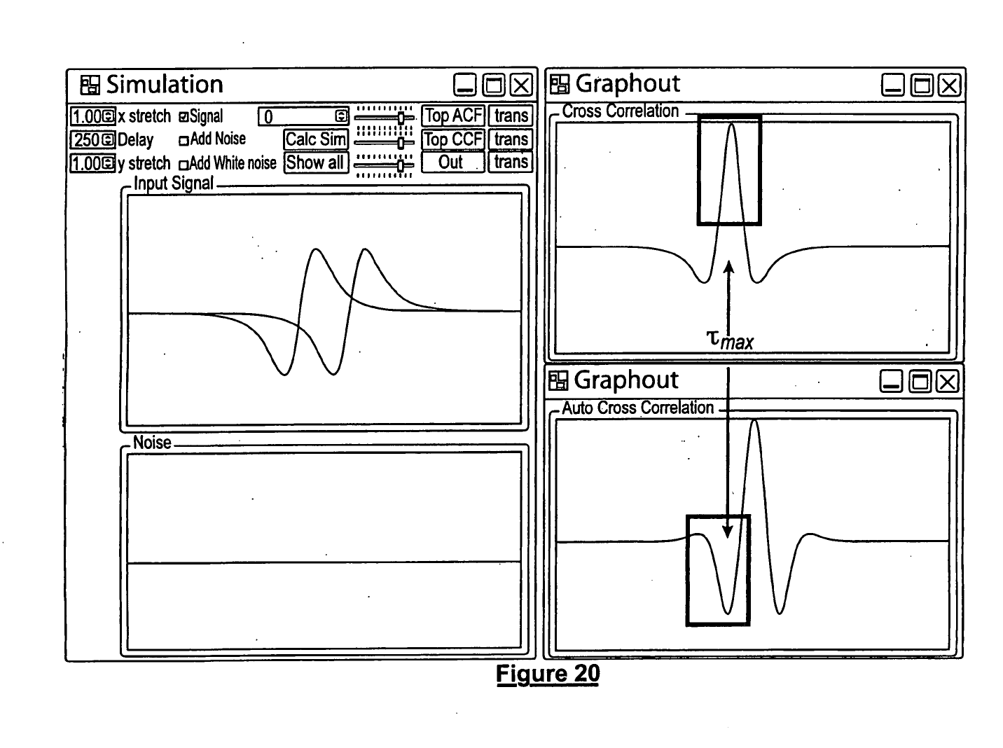

It is noted that alternative embodiments may utilise either of these two signal processing approaches, or a different signal processing approach. One such alternative signal processing approach is discussed in the following with reference to FIGS. 20 to 25.

The present embodiment further provides a light barrier (not shown) at the entrance to the magnetic casing, so the exact time window when a detection can occur and when it cannot occur is known. Because it is known when the cross-correlation maximum might occur, it is also known when this maximum in the cross correlation function can not be caused by a contaminant. In this way, when a false positive is caused by changes in the noise environment at a time other than when a contaminant may be passing the sensor, the false positive can be identified as such and discarded.

The software gradiometry will now be discussed in more detail. A gradiometer in general is a way to measure weak signals in noisy environment. In the present embodiment there are two SQUID sensors 170, 180 separated by a distance of 50 mm, operating to pick up the signal. An underlying assumption is that both sensors 170, 180 are measuring the same noise signal, with the same phase, and that the signal source of interest (namely, the magnetic contaminant) is very much closer to the sensors 170, 180 than all the noise sources in the environment. For this assumption to be reasonable, noise sources close to the sensors should be shielded or dealt with in some way to keep such a noise level low, as noise that is measured with different phases at different sensors can not be cancelled easily.

Noise that is measured with the same phase and amplitude at both sensors 170, 180 can be cancelled out by the gradiometric approach, without cancelling the signal of the contaminant which will be measured with a different amplitude by the different sensors. Gradiometry does, however, cancel out the common mode component of the signal of interest.

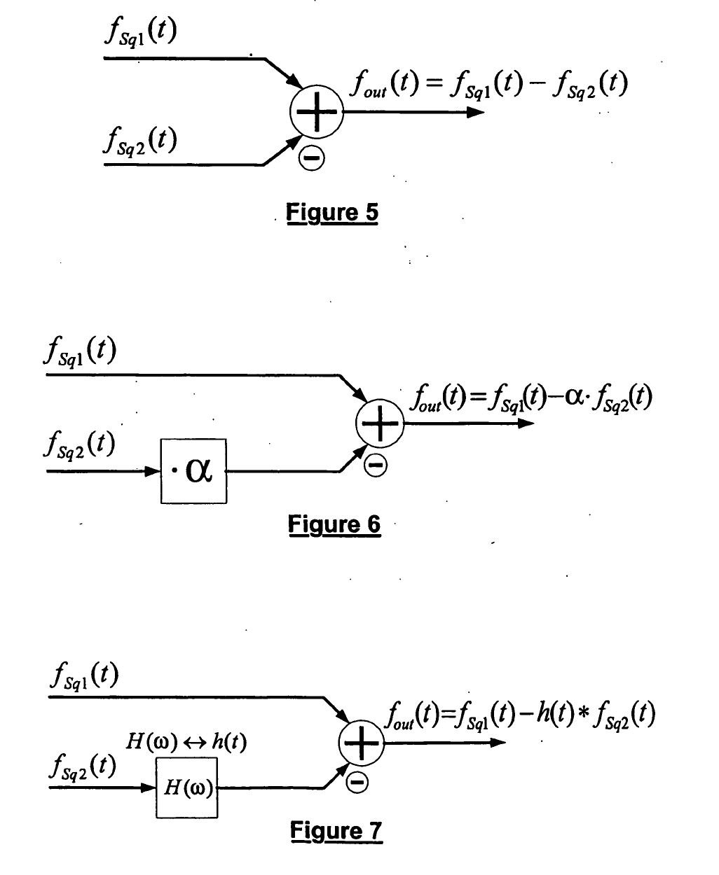

The simplest way of creating a gradiometer is by simply subtracting the reference channel (f_{Sq2}(t)) from the signal channel (f_{Sq1}(t)), as shown in FIG. 5. To allow for circumstances where the two channels have a different level of noise, while still providing noise reduction, the simple subtraction is extended to include regression in the time domain. In this approach, as shown in FIG. 6, one of the signals, in this embodiment f_{Sq2}(t), is multiplied by a constant factor α. It is to be expected that there will be a different level in the two channels because the two SQUIDs 170, 180 are unlikely to have identical properties and therefore will have different transfer functions.

To calculate the factor α, a regression in the time domain is performed. This means the gradiometer needs to be configured before actual measurements. Factor α will be calculated based on measurements of the background noise prior to any sample measurement.

The two channels of SQUID signal output are f_{Sq1}(t) and f_{Sq2}(t). After performing an A/D conversion the signals are discrete in time and amplitude. The discrete nature of the amplitude can be neglected for present purposes. Analogue signal f_{Sq1}(t) becomes discrete signal f_{Sq1}[n] with n=0, 1, 2 . . . . Each point n of the discrete function equals a value of the continuous function at the time t=(1/fₛ).n. The value fₛ is the sampling frequency of the A/D converter. The output signal of a gradiometer with regression in the time domain with multiple reference channels is:

$${f}_{signal} [ n ] = {\sum }_{i} {α}_{i} \cdot {f}_{reference , i} [ n ] \qquad ( 2 )$$

The coefficients α_{1, 2, . . . , n} are determined by:

α=Γ⁻¹·b (3)

Where α represents the vector with components α_{1, 2, . . . , n} and b is the vector with the components:

$${b}_{i} = {\sum }_{n} [ {f}_{signal} [ n ] \cdot {f}_{reference , i} [ n ] ] \qquad ( 4 )$$

The matrix Γ has the components

$${Γ}_{ij} = {\sum }_{n} [ {f}_{reference , i} [ n ] \cdot {f}_{reference , i} [ n ] ] \qquad ( 5 )$$

In our case we have only one reference signal, so the matrix Γ becomes a scalar:

$${\sum }_{n} {{f}_{Sq 2} [ n ]}^{2} \qquad ( 6 )$$

Also the vector b is reduced to one component

$${b}_{1} = {\sum }_{n} [ {f}_{Sq 1} [ n ] \cdot {f}_{Sq 2} [ n ] ] \qquad ( 7 )$$

Therefore our calculation of the coefficient α is:

$$α = \frac{{\sum }_{n} [ {f}_{Sq 1} [ n ] \cdot {f}_{Sq 2} [ n ] ]}{{\sum }_{n} {{f}_{Sq 2} [ n ]}^{2}} \qquad ( 8 )$$

This factor α is calculated during a configuration process, which solves equation (8) for a given amount of samples n.

For the regression in the time domain, the correction of the reference channel f_{Sq2}(t) is performed, so the noise in the signal channel f_{Sq1}(t) has the best possible match to the noise in the reference channel f_{Sq2}(t). By then subtracting these matched signals provides for an optimised time regression noise cancellation. However, regression in the time domain only changes the level of the reference channel f_{Sq2}(f).

FIG. 7 illustrates regression in the frequency domain, which changes the spectrum of the reference channel f_{Sq2}(t). That means the simple multiplication with α in the arrangement of FIG. 6 is replaced by a filter with the transfer function H(ω), as shown in FIG. 7. For a system with multiple reference channels with spectra F_{reference,1}(f), the spectrum of the signal channel F_{signal}(f) is:

$${F}_{Signal} ( f ) = {\sum }_{i} {H}_{α} ( w ) \cdot {F}_{reference , i} ( f ) \qquad ( 9 )$$

Simplified for a two channel system:

F_{signal}(f)=H_{α}(ω)·F_{reference}(f) (10)

Therefore:

$${H}_{α} ( w ) = \frac{{F}_{signal} ( f )}{{F}_{reference} ( f )} \qquad ( 11 )$$

By calculating H(ω) in this manner, the reference channel f_{Sq2}(t) is filtered such that the filtered reference signal matches the signal channel. The calculation of H(ω) is carried out when all channels measure only the noise environment, and no signal is applied, and is thus conducted when no products are passing through the system 100.

In the preferred embodiment, the calculation of H(ω) is repeated over time to adapt the system to changes in the environment noise. The present invention recognises that during operation, polluted and contaminated products are the exception, as the majority of the products can be expected to not be contaminated. Thus, no signal will be detected most of the time, and at such times acquired data can be taken to be background noise data and thus be used to re-configure the gradiometers, the time regression coefficient α and/or the frequency regression transfer function H(ω), on an ongoing basis. Such an ability of the system to adapt to changing noise conditions is valuable in factory-type applications in which the system is required to operate for long periods without being taken off-line for re-configuration.

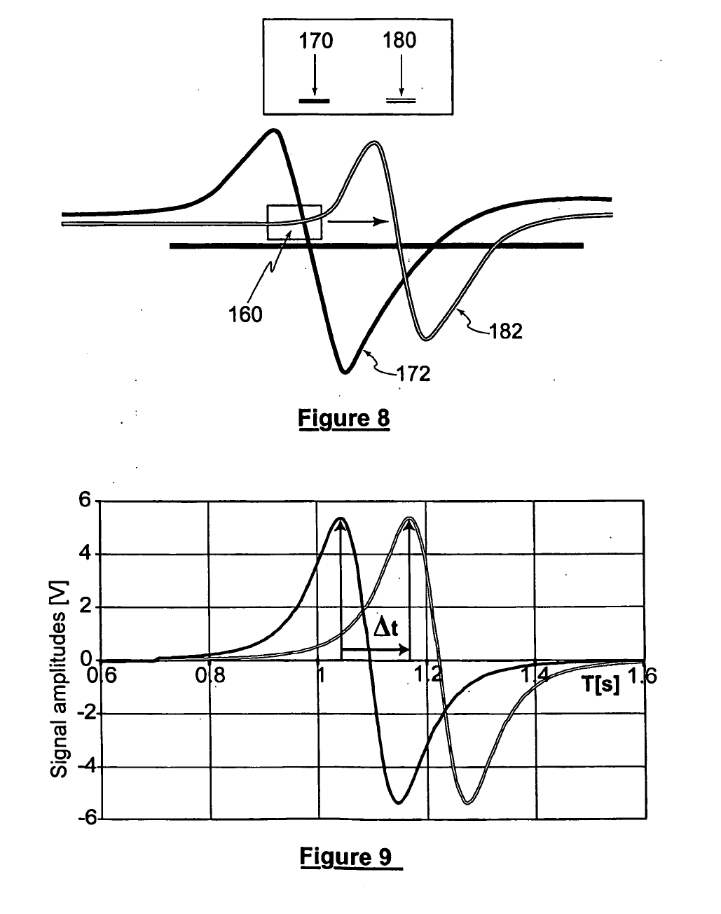

We now turn to the second of the two signal processing techniques applied in the present embodiment, being the generation of a cross correlation of the two SQUID signals. When a contaminant magnetic particle passes the two SQUIDs 170, 180, which are located in line along the conveyor belt separated by a distance of 50 mm, both SQUIDs record substantially the same signal of interest, but with a time delay depending on the particle speed and baseline distance. FIG. 8 is an enlarged view of a portion of the system 100 of FIG. 2, showing the alignment of the SQUIDs 170, 180, and the time-delayed nature and similar shape of the recorded signals 172, 182 produced by each respective SQUID sensor.

FIG. 9 illustrates the SQUID signals after signal matching is performed, illustrating the time delay Δt.

The second signal processing technique of the present embodiment recognises that the time delayed nature of the signal 182 with respect to the signal 172 can be used to distinguish whether noise has caused a measured signal, or whether there is a signal from a magnetic particle. The cross correlation function is:

CC(τ)=∫_{-∞}^{∞}f_{Squid1}(t)f_{Squid2}(t+τ)dt (12)

The discrete cross correlation function is given by:

$$CC [ n ] = {\sum }_{m = - ∞}^{∞} {f}_{Squid 1} [ m ] {f}_{Squid 2} [ m + n ] \qquad ( 13 )$$

Where f_{Squid1} and f_{Squid2} are the two SQUID signals 172, 182, t and z are time values, and n and m are the numbers of the samples in the discrete case. For simplification the following refers to the continuous case, however it will be appreciated that key characteristics apply similarly to the discrete case.

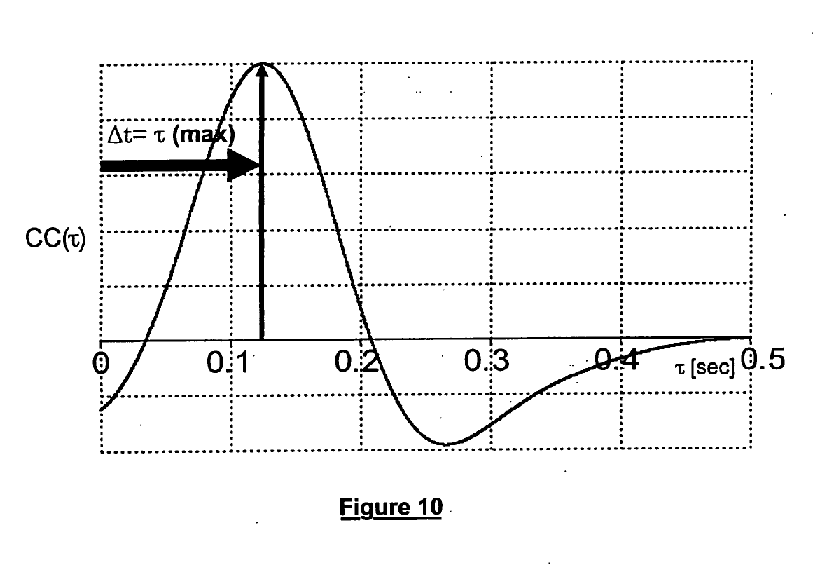

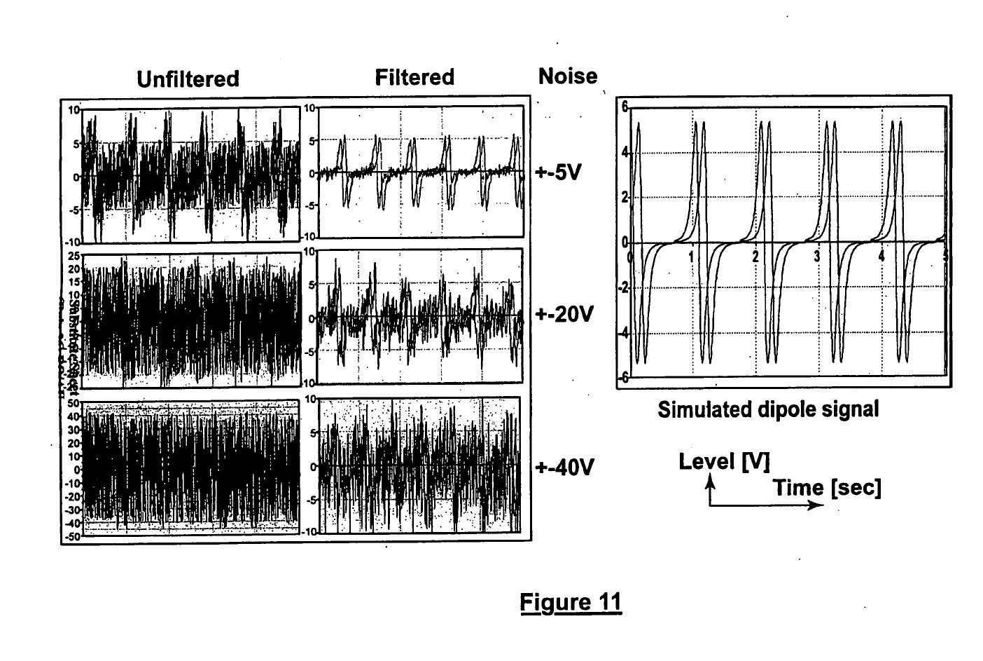

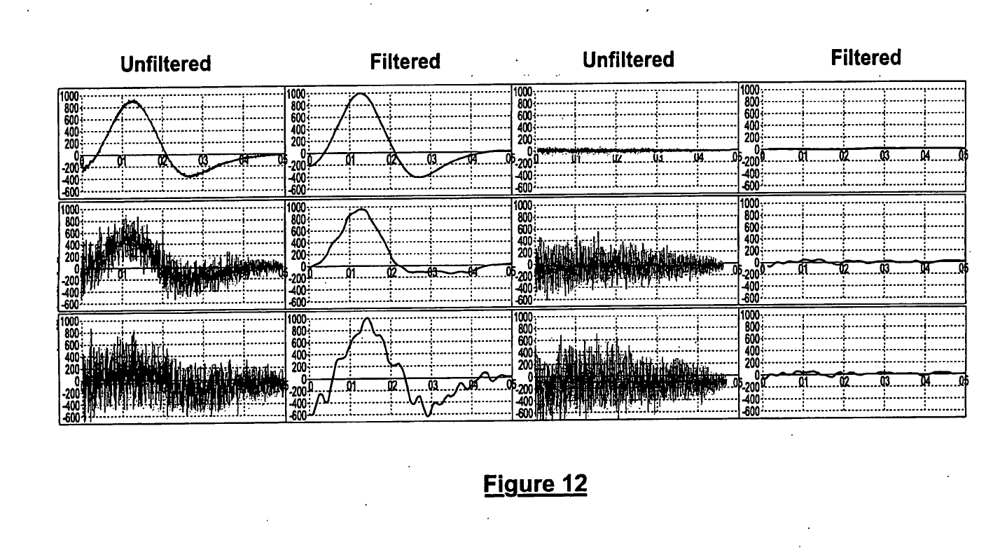

With knowledge of the speed of conveyor belt 140 and the geometry of SQUIDs 170, 180, the cross correlation function of signals 172, 182 becomes predictable. White noise is recorded at the same time by each sensor 170, 180, and will thus cause a cross correlation to take the shape of a delta impulse at τ=0. On the other hand, the signal recorded from a passing magnetic contaminant will cause the cross correlation to have a maxima at a specific value of τ corresponding to Δt, referred to as τₘₐₓ. FIG. 10 illustrates the cross correlation of the matched SQUID signals 172, 182 in the absence of noise, illustrating the expected maxima at τₘₐₓ.

Accordingly, where white noise is mixed with the signals 172, 182, the white noise component is confined to the τ=0 portion of the function, and is thus separated from the signal component in the cross correlation function, which is then identifiable at τₘₐₓ.

In addition to separating out white noise, FIG. 10 further illustrates that a consideration of the cross correlation can allow the expected maxima at τₘₐₓ to be separated from any external noise signal which is not itself correlated at τ=τₘₐₓ. Such noise signals would commonly include external noise, A/D noise, SQUID noise, three phase power noise and the like. For example, sine shaped noise signals (e.g. 50 Hz, or other frequencies) have multiple maxima in the correlation function. The cross correlation function of two identical sine waves is a sine wave and has periodic maxima. The location of these maxima depend on the periodicity of the sine wave, and are thus predictable in their location for a noise source of relatively stable frequency.

By providing the arrangement of FIG. 2, the present embodiment provides for the value of τₘₐₓ to not be equal to zero, and to be controllable by appropriate selection of conveyor belt speed and SQUID baseline separation. Accordingly, τₘₐₓ can be controlled to be located in a ‘quiet’ portion of the cross correlation function, for example to avoid coincidence of τₘₐₓ with the location of 50 Hz or 60 Hz noise, and harmonics thereof, in the cross correlation. In this arrangement, even if the amplitude of each noise signal is higher than any magnetic contaminant signal amplitude, the noise can be separated in the correlation function, enabling an improved determination to be made as to whether any magnetic particle is recorded by the SQUIDs 170, 180.

It is known that, for a valid detection signal to occur, the signal must not have existed immediately before nor immediately after it's occurrence. Further, by providing the light barrier, it is known at which times each product passes the sensor and thus the times at which such a valid signal can arise. A signal which does not satisfy both these requirements can be identified as a false positive.

While the first of these requirements can be found to be violated simply by noting that the maxima does not appear and disappear in the appropriate manner, nevertheless the system must operate to detect valid signals in the presence of noise signals. This problem is addressed in the present embodiment by exploiting the recognition that the locations of the maxima in the cross correlation caused by a sinusoidal noise source depend on the periodicity of the sine wave, but are independent to phase shifts, as the correlation is phase blind. Accordingly, the system obtains a “noise only”, or background, cross correlation from the SQUID signals sensed just before and/or just after a product passes the sensors. The background cross correlation is then subtracted from the cross correlation obtained while the product passes the sensors. Because the cross correlation of the periodic noise signals is phase blind, this subtraction is not additive but provides a cancelling of noise components which exist in both the background cross correlation and the signal cross correlation. Thus, compensation can be made even for a sinusoidal or quasi-periodic noise signal which causes a maximum in the cross-correlation function at τₘₐₓ, provided such a noise signal exists both in the background cross correlation and the signal cross correlation.

Yet another technique applied in the present embodiment to eliminate false positives is based on the recognition that the shape of a valid cross correlation function caused by a magnetic contaminant is predictable. This is because the signal shape itself, caused by a pre-magnetized sample, is known, as illustrated in FIGS. 2B to 2I. Further valid signal shapes, and their associated cross correlation shapes, can be predicted for alternative dipole/sensor geometries. Together with a knowledge of τ, this imposes particular characteristics upon a valid cross correlation, such that if the shape of a sensed signal and/or the shape of the cross correlation of the two SQUID signals does not possess such characteristics, the sensed signal can be determined to be a false positive and discarded. Whether or not a given cross correlation (or a given sensed signal) has an acceptable shape is determined by cross correlating it with a pre-determined ‘proper’ cross correlation (or a pre-determined ‘proper’ signal). The outcome of this further cross correlation provides a measure of an extent to which the cross correlation (or sensed signal) matches an allowable shape.

Where a maximum occurs in the cross correlation at or proximal to the amplitude of and area beneath the maximum are further indicators of whether or not a valid sensed signal has arisen. Accordingly, the common technique of scaling the cross correlation to have a maximum of one is not applied in the present embodiment, and instead the absolute of the cross correlation function is obtained. This absolute value is of interest because it gives a value of the overlapping areas of the signal, which can be interpreted as a value strongly connected with the power of the correlated signal. This power value can give some information about the measured signal and can further be used to distinguish between noise and expected signal.

Yet another technique applied in the present embodiment to separate noise from the signal of interest is to apply a low pass filter to the output signals produced by the SQUIDs 170, 180. Due to the controlled environment provided by the system 100 of FIG. 1, it is known that the frequency components of a signal of the type shown in FIG. 2E caused by a magnetic particle will be related to the speed of the conveyor belt 140. Normal conveyor belt speeds will cause such frequency components to be in a band of interest having an upper limit around 20-30 Hz and a lower limit of less than 1 Hz. Accordingly, aggressive low pass filtering can be applied to remove frequency components above this range, particularly to remove 50 or 60 Hz noise. The present embodiment utilises a software implementation of a digital approximation of the absolute transfer function of an analogue twentieth order Chebyshev low pass filter. The filter design is performed within the software so that the filter order and design can be changed on an ongoing basis.

The present embodiment of the invention further implements a high pass filter in order to remove any DC offset caused by differences between the SQUIDs and other components.

Additionally, because the direction in which the samples pass is known, and the value of τₘₐₓ is known, only small parts of the cross correlation function need to be calculated, even if the sampling window is very wide.

FIGS. 11 and 12 illustrate the value of low pass filtering the signal of each SQUID. The +/−5V signals expected to be output from the two SQUIDs in the absence of noise and in response to a series of passing dipoles are shown in the right-hand plot of FIG. 11. To these signals were added noise levels of +/−5V, +/−20V and +/−40V, as shown in the left-hand column of the three rows of plots on the left-hand side of FIG. 11. These signal+noise plots were then low pass filtered using the abovementioned Chebyshev filter, producing the substantially improved plots in the right hand column of the three rows of plots on the left-hand side of FIG. 11.

FIG. 12 further illustrates the value of low pass filtering the signals shown in FIG. 11. From left to right, the columns of FIG. 12 show: plots of the cross correlation of the unfiltered two SQUID signals; plots of the cross correlation of the two filtered SQUID signals; plots of the cross correlation of unfiltered noise only; and plots of the cross correlation of filtered noise only. The signal level is +/−5V in the left-hand two columns. From top to bottom, the rows show the effect of varying noise levels of +/−5 V, +/−20 V and +/−40 V.

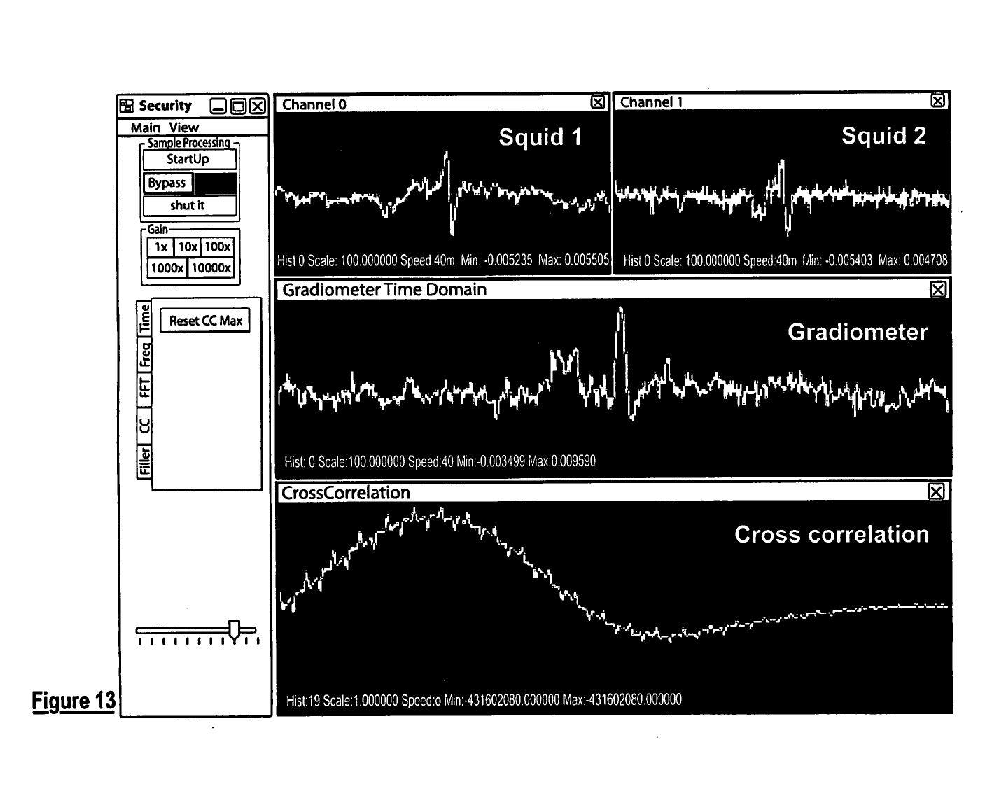

A range of measurements have been performed using the system of FIG. 1 to illustrate the performance of gradiometry and cross correlation, and to show how noise and other external signals not generated by a sample can be reduced. FIG. 13 is a screenshot of the sensed SQUID signals, the gradiometer output, and the cross correlation output obtained while measuring a sample comprising a 15 mm long stainless steel wire. Such a sample has actually been found within a food product. For the purposes of illustrating the detection capability of the system 100, the sample was not pre-magnetized so as to provide a weak sample closer to the detection limit, however it is noted that in practice this sample would have been pre-magnetized and would therefore cause much larger signals.

Referring to FIG. 13, it can be seen that the gradiometer signal has a higher amplitude than each single channel signal. It can further be seen here how the signal to noise ratio of the cross correlation shown at the bottom of FIG. 13 is better than that of the gradiometer.

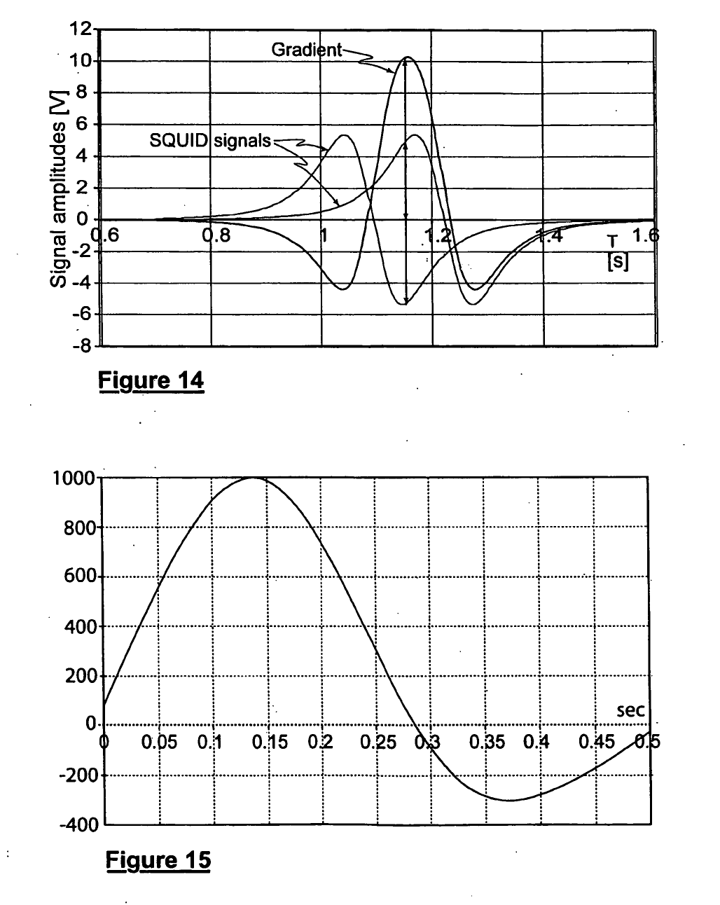

FIG. 14 is a plot of the recorded signals of a stainless steel needle found in meat. It is a fairly strong magnetic sample and has been pre-magnetized. FIG. 14 illustrates that the gradiometer signal amplitude is greater than that of either magnetometer channel on its own, because the shape of each magnetometer recorded signal includes both a distinct maximum and a distinct minimum, and because the time delay (defined by speed and geometry) causes the minimum of the first magnetometer signal to substantially coincide with the maximum of the second magnetometer signal.

The cross correlation of the SQUID magnetometer measurements of FIG. 14 is shown in FIG. 15, and closely matches the expected cross correlation shape estimated in FIG. 10.

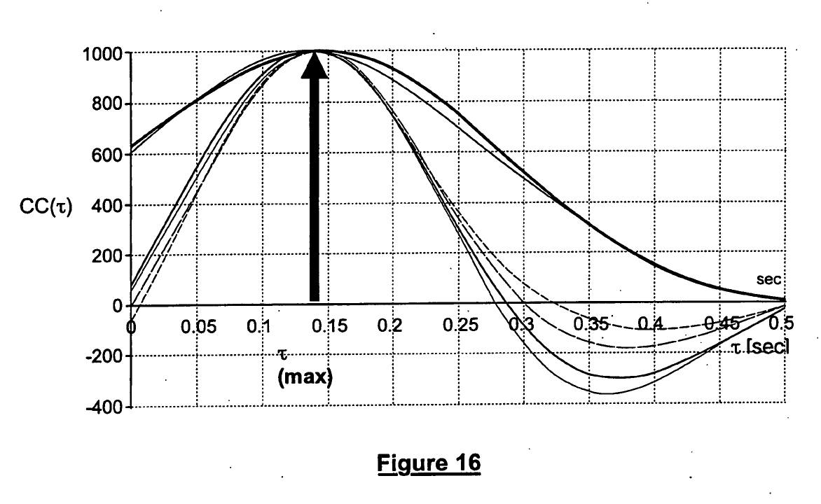

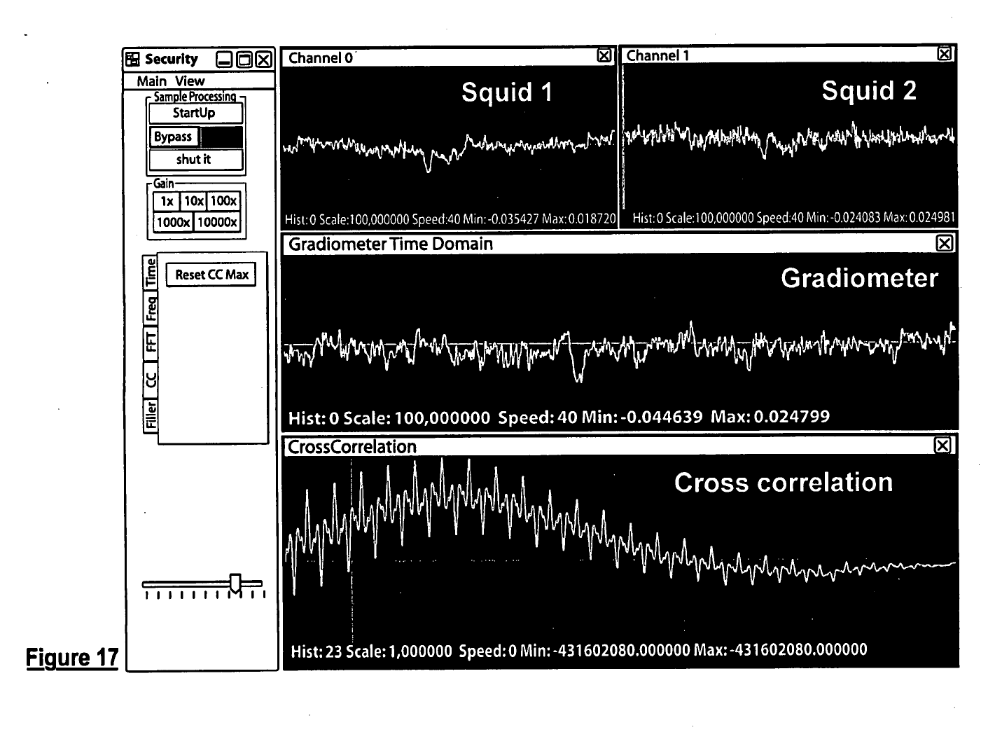

FIG. 16 is a plot of the cross correlation of SQUID signals obtained for a variety of passing samples. All cross correlations are standardised to a maximum value of 1000. FIG. 16 illustrates that the position of the maximum of each cross correlation is always in the same position (τₘ, m→mₘₐₓ), for a constant speed. τₘ is the time that a passing sample takes to travel from the first SQUID magnetometer to the second SQUID magnetometer. FIG. 16 further illustrates that, while the shape of the various cross correlations can vary, such variations are relatively minor. Accordingly a library of such possible correlation shapes may be stored, so that an obtained cross correlation can be cross correlated with possible correlation shapes. This further cross correlation serves to determine whether the shape of the obtained cross correlation sufficiently matches a possible signal shape, and if not the obtained cross correlation can be discarded as being a false positive.

FIG. 17 illustrates the two SQUID magnetometer output signals, the gradiometer output, and the cross correlation output when a ferrous sample 1.5 mm in diameter was passed through the system 100. Such a small sample has a very small magnetic moment, so that the signal recorded by each SQUID magnetometer is close to or even below the background noise level. While an assessment of either SQUID output and of the gradiometer output does not clearly reveal a positive detection event distinguishable from noise, the cross correlation still shows a clear signal.

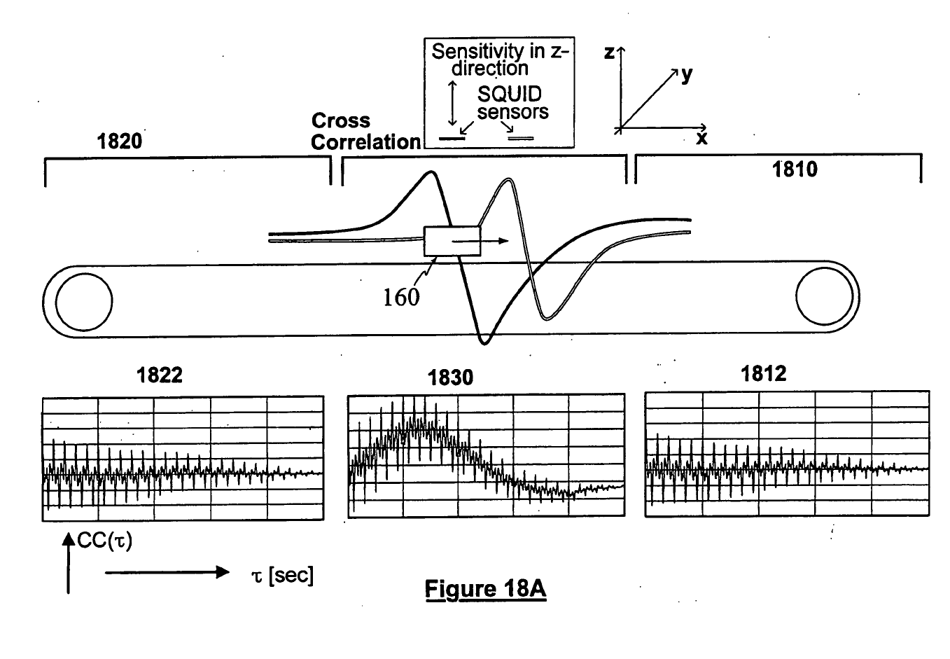

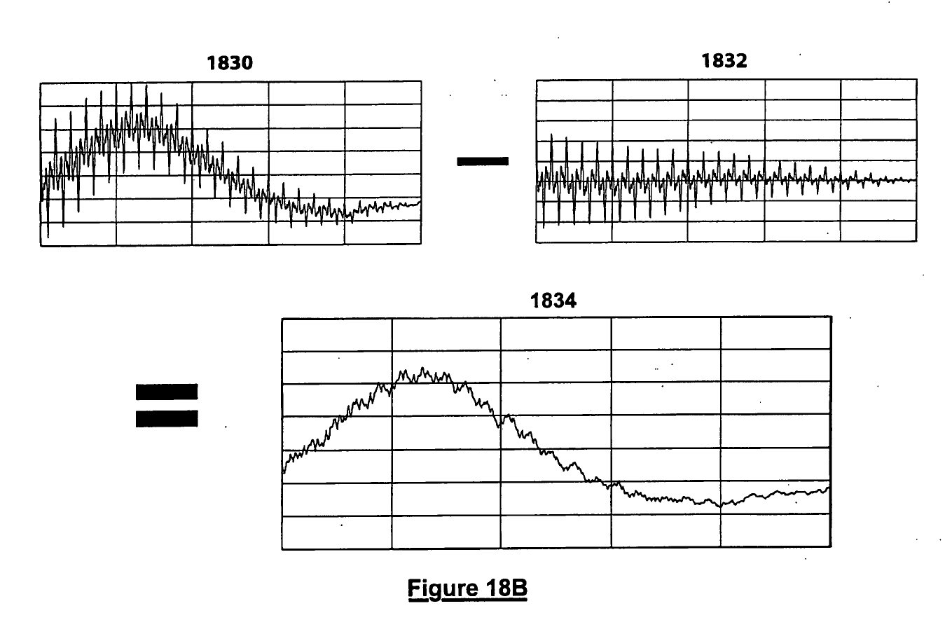

The signal to noise ratio of the cross correlation can be further improved by subtracting the correlation of the background noise from the correlation of the signal+noise. FIGS. 18A and 18B illustrate the retrieval of a noise-only cross-correlation of the signals from the two SQUIDs from before and after the sample passes, and the subtraction of the noise-only cross-correlation from the signal+noise cross-correlation to improve sensitivity;

As illustrated in FIG. 18A, the correlation of the background noise is obtained at times when no sample is passing the SQUID magnetometers. Thus, in the empty region of the conveyor belt indicated at 1810, before the sample 160 passes the SQUIDs 170, 180, signals are obtained from the SQUIDs of noise only, and cross correlated to produce a background correlation 1812. Similarly, in the empty region of the conveyor belt indicated at 1820, after the sample passes the SQUIDs 170, 180, signals are obtained from the SQUIDs of noise only, and cross correlated to produce a background correlation 1822. Background correlations 1812 and 1822 are averaged to produce an estimate 1832 of the noise-only background correlation present at the time the sample 160 is actually being sensed by the SQUIDs.

As illustrated in FIG. 18B, estimated noise correlation 1832 is then subtracted from the signal+noise correlation 1830 to produce a noise-reduced correlation profile 1834. As previously discussed such a subtraction leads to a reduction in noise in the correlation profile because the cross correlation of quasi-sinusoidal noise signals is phase blind.

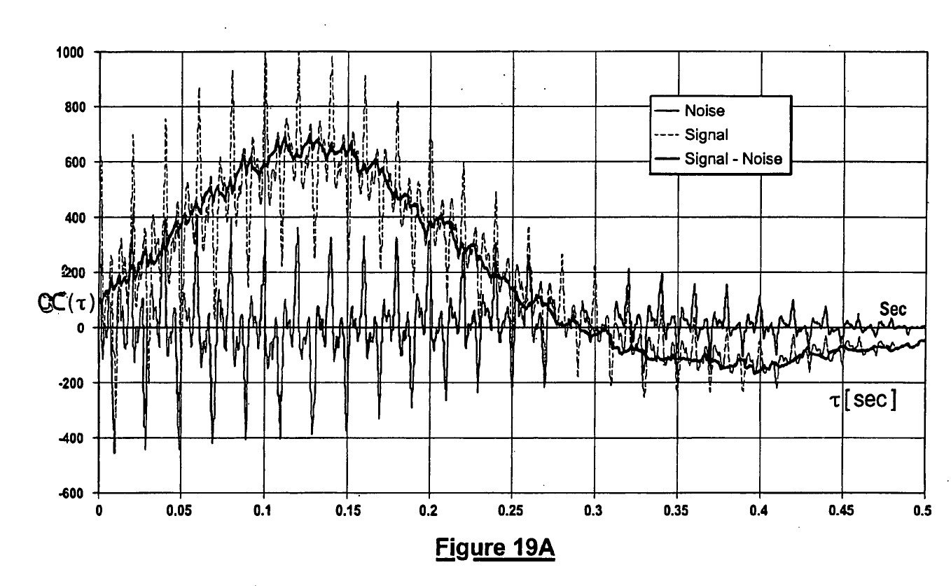

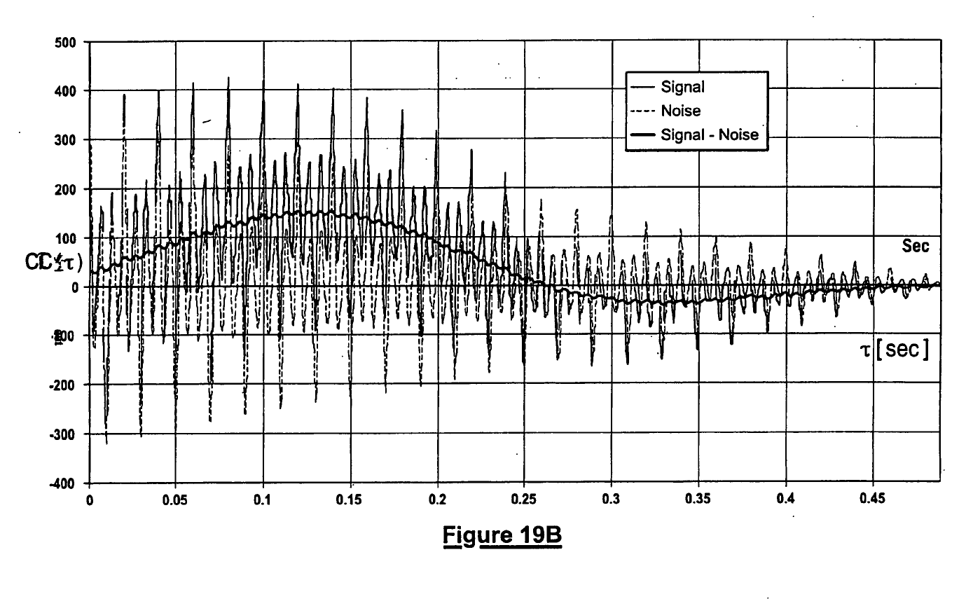

FIGS. 19A and 19B illustrate subtraction of the noise-only cross-correlation from the signal+noise cross-correlation where the signal cross-correlation is larger (FIG. 19A) and smaller (FIG. 19B) in peak amplitude than the noise-only cross-correlation, and illustrate the utility of the background correlation subtraction even where the noise in the cross correlation approaches or is greater in magnitude than the signal cross correlation.

Thus, it is noted that the correlation function suppresses white noise, intrinsic noise, 1/f noise and all other uncorrelated noise sources, unlike the gradiometer. Further, correlated noise sources can be reduced as long as they add no major component in correlation function at the point of the time delay of the events.

The system 100 of FIG. 1 further utilises a noise reduction technique in accordance with the first to third aspects of the present invention. This technique recognises that the mathematics of the correlation functions offers another means for noise suppression. We consider the signal of two channels s₁(t) and s₂(t). In the case of common mode noise, each signal consists of a possible event signal e_{1,2}(t) (in which ideally e₁(t)=e₂(t+τ)), and the identical noise n(t), so that:

s_{1,2}(t)=e_{1,2}(t)+n(t) (14)

One of two possible cross correlations CC(τ) of the input signals s₁(t) and s₂(t) is:

CC(τ)=∫s₁(t)·s₂(t+τ)dt (15)

CC(τ)=∫(e₁(t)+n(t))·(e₂(t+τ)+n(t+τ))dt (16)

CC(τ)=∫(e₁(t)e₂(t+τ)+n(t)e₂(t+τ)+e₁(t)n(t+τ)+n(t)n(t+τ))dt (17)

Due to the non linearity of the correlation function, the cross correlation of the noise is producing not only the auto correlation AC of the common mode noise:

CC(τ)=∫(n(t)n(t+τ))dt (18)

and the cross correlation of the event:

CC(τ)=∫(e₁(t)e₂(t+τ))dt (19)

but is also producing the correlation of mixed terms.

CC(τ)=∫(n(t)e₂(t+τ)+e₁(t)n(t+τ))dt (20)

Thus, simply subtracting the auto correlation of one channel from the cross correlation of the two channels would successfully remove the auto correlation of the noise, but would not remove the mixed event+noise terms. Instead, such a subtraction would add more mixed terms from the auto correlation, which produces different mixed terms:

AC(τ)=∫(e₁(t)e₁(t+τ)+n(t)e₁(t+τ)+e₁(t)n(t+τ)+n(t)n(t+τ))dt. (21)

The present technique recognises and address the problem of whether a combination of auto and cross correlation functions can be found which mathematically removes the common mode noise, including removal of mixed event+noise terms, to produce only correlation terms of event components. In considering all possible cross and auto correlation functions in exploded form, it can be seen that all mixed event+noise terms arise twice:

CC(τ)₁=∫(e₁(t)e₂(t+τ)+n(t)e₂(t+τ)+e₁(t)n(t+τ)+n(t)n(t+τ))dt (22)

CC(τ)₂=∫(e₂(t)e₁(t+τ)+n(t)e₁(t+τ)+e₁(t)n(t+τ)+n(t)n(t+τ))dt (23)

AC(τ)₁=∫(e₁(t)e₁(t+τ)+n(t)e₁(t+τ)+e₁(t)n(t+τ)+n(t)n(t+τ))dt (24)

AC(τ)₂=∫(e₂(t)e₂(t+τ)+n(t)e₂(t+τ)+e₂(t)n(t+τ)+n(t)n(t+τ))dt (25)

By taking the combination

CC₁(τ)+CC₂(τ)−AC₁(τ)−AC₂(τ) (26)

we produce the output signal

C(τ)_{combine}=∫(e₁(t)e₂(t+τ)+e₂(t)e₁(t+τ)−e₁(t)e₁(t+τ)−e₁(t)e₁(t+τ))dt (27)

which suppresses the common mode noise, theoretically completely. Taking the negative of equation (26) will also remove all noise and mixed event+noise terms. A mathematically identical way to come to this outcome is to build the auto correlation function of the gradiometer signal.

It is noted that the auto-cross-correlation function of equations (26) and (27) contains the autocorrelation of the time series of each signal s₁(t) and s₂(t), and also contains both cross correlations between s₁(t) and s₂(t). As for the cross correlation techniques discussed in the preceding, each cross correlation component in equations (26) and (27) will have a maximum which occurs at the known time delay τₘₐₓ. Accordingly, the auto-cross-correlation possesses the same benefits as previously discussed in relation to τₘₐₓ being not equal to zero and being controllable by selection of baseline separation and conveyor speed.

FIG. 20 is four plots of, respectively, first and second SQUID signals produced by a passing magnetic dipole, a zero noise signal, the cross correlation of the first and second SQUID signals, and the auto-cross correlation of the first and second SQUID signals. This figures illustrates the shape of the auto-cross-correlation in the absence of noise, and it's comparable suitability as an event detector in such conditions when compared to the cross-correlation. Notably, at τₘₐₓ there exists a maxima in the cross correlation, and a first minima in the auto-cross correlation.

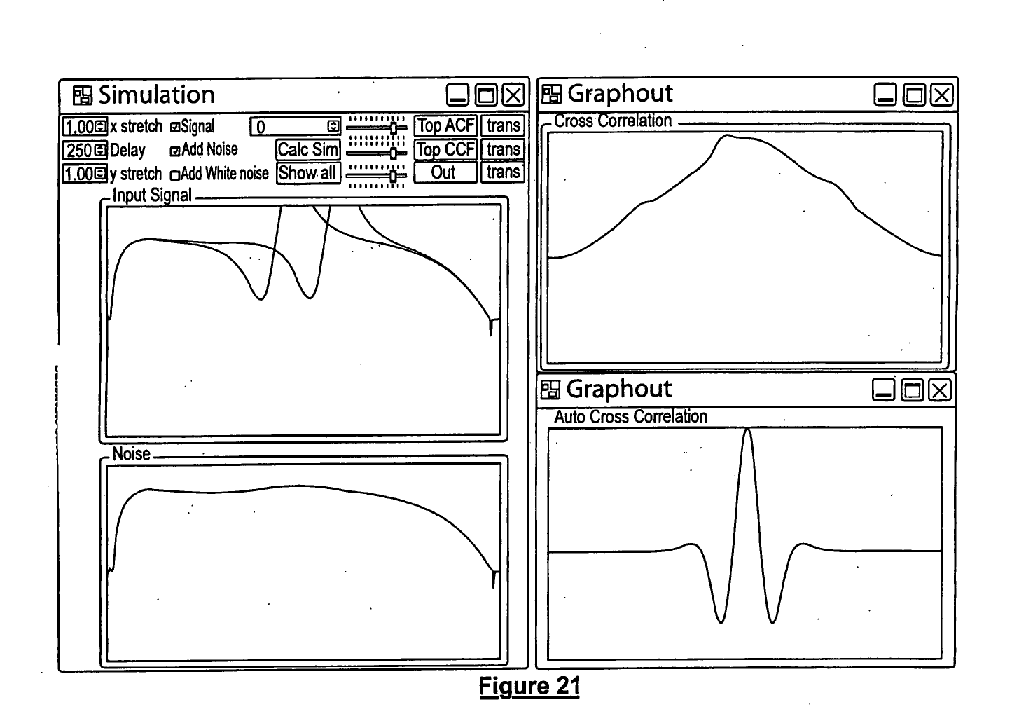

FIG. 21 is four plots of, respectively, first and second SQUID signals produced by a passing magnetic dipole in the presence of noise, a non-zero noise signal, the cross correlation of the first and second SQUID signals, and the auto-cross correlation of the first and second SQUID signals. This figure illustrates the substantial deterioration in the performance of the cross correlation as a tool for detecting the signal event caused by this noise signal, and illustrates the continued good performance of the auto-cross-correlation as such a tool.

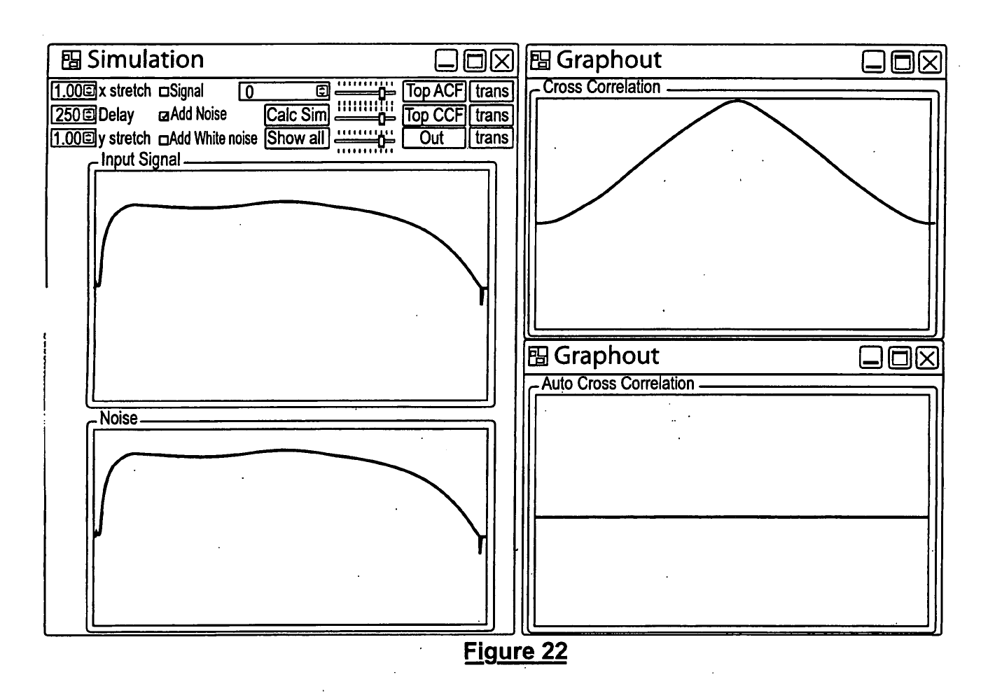

FIG. 22 is four plots of, respectively, identical first and second SQUID signals produced in the presence of noise and in the absence of any passing magnetic dipole, a non-zero noise signal, the cross correlation of the first and second SQUID signals, and the auto-cross correlation of the first and second SQUID signals. This figure illustrates the corruption of the cross-correlation output by such a noise environment, and the continued accurate performance of the auto-cross-correlation which correctly indicates that no event has occurred.

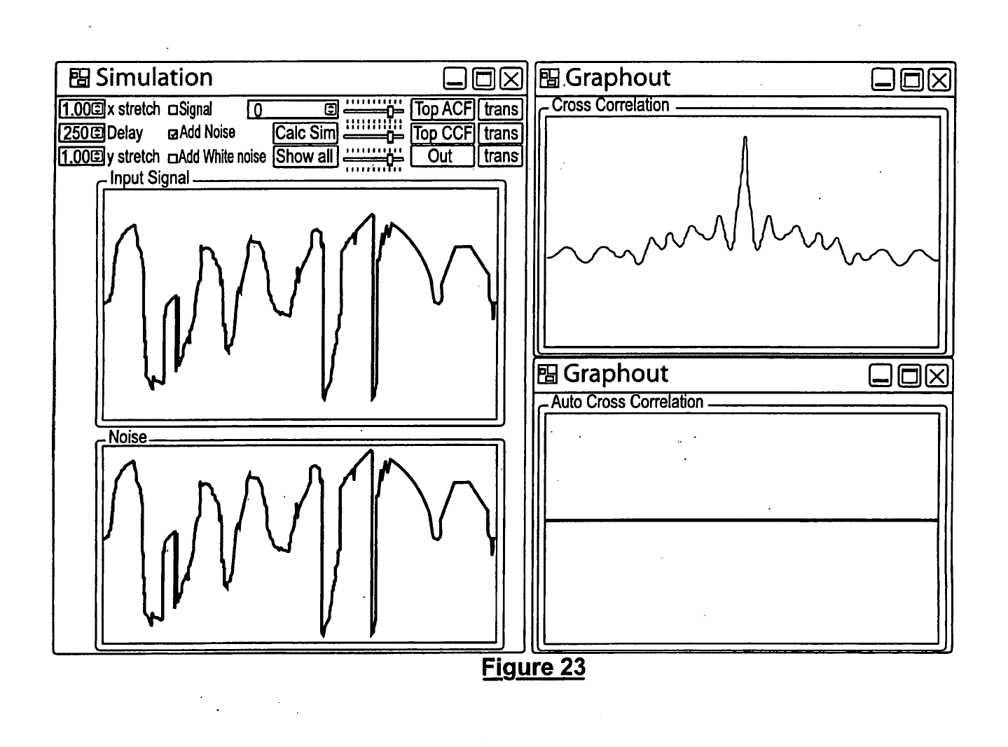

FIG. 23 is four plots of, respectively, identical first and second SQUID signals produced in the presence of complex noise and in the absence of any passing magnetic dipole, a non-zero complex noise signal, the cross correlation of the first and second SQUID signals, and the auto-cross correlation of the first and second SQUID signals. This figure also illustrates the corruption of the cross-correlation output by such a noise environment, and the continued accurate performance of the auto-cross-correlation which correctly indicates that no event has occurred.

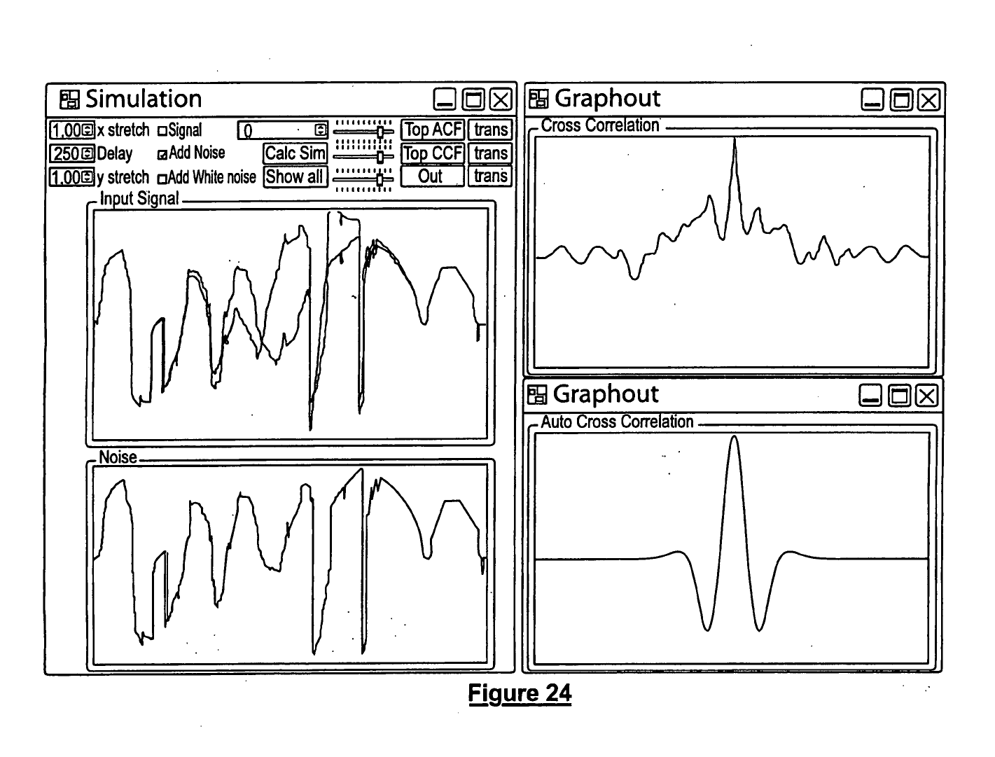

FIG. 24 is four plots of, respectively, first and second SQUID signals produced by a passing magnetic dipole in the presence of complex noise, a non-zero complex noise signal, the cross correlation of the first and second SQUID signals, and the auto-cross correlation of the first and second SQUID signals. This figure also illustrates the corruption of the cross-correlation output by such a noise environment, and the continued accurate performance of the auto-cross-correlation which correctly indicates that an event has occurred.

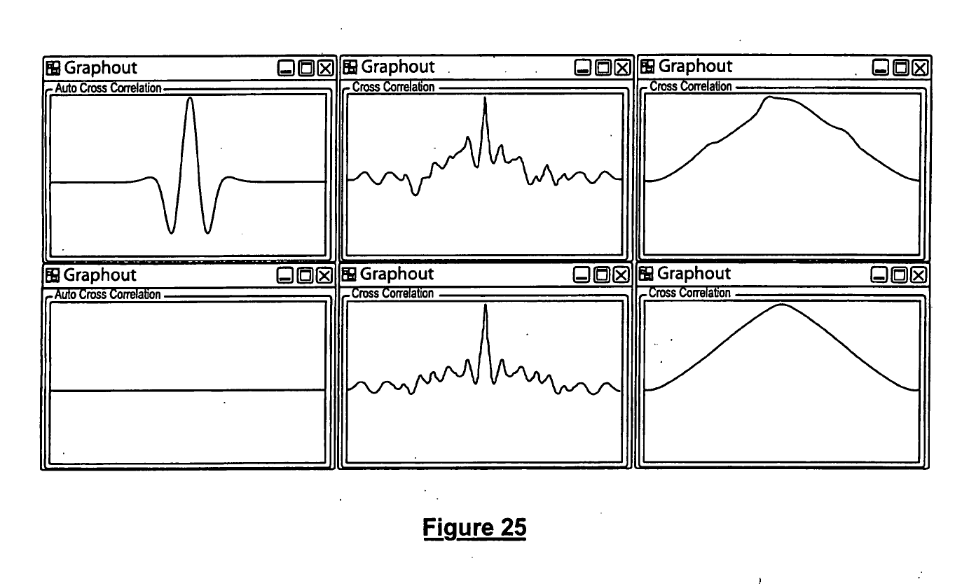

The left-hand and centre columns of FIG. 25 compare sub-plots of FIG. 24 to corresponding sub-plots of FIG. 23, while the right-hand column compares a sub-plot of FIG. 21 to a corresponding sub-plot of FIG. 22. The left-hand column illustrates the clear distinction provided by the auto-cross-correlation between an event or a non-event, even in the presence of widely varying noise conditions. The centre and right-hand columns illustrate the relatively poor performance of the cross correlation in distinguishing between an event and a non-event.

As an example for the effectiveness of the described noise reduction and signal extraction method, we simulate the detection of a magnetic dipole passing two SQUID magnetometers and compare conventional magnetometry and gradiometry with the present embodiment of the invention. FIG. 31 shows the simulation of one possible signal of a magnetic dipole, recorded by a magnetometer. The topmost curve is the theoretical signal of two dipoles passing a single magnetometer without added noise. The two curves below this one show the two input channels with a time delay in the dipole signal and added noise. The noise in each channel consists of 1.4 a.u. peak-to-peak of low pass filtered white noise. Also, in both channels the same common mode noise has been added, which is a stochastic low frequent signal of 1.0 a.u. peak to peak. The dipole signal itself has an amplitude of ±0.5 a.u peak to peak, as can be seen from the topmost curve.

The bottom curve in FIG. 31 shows the gradiometer signal of the two input signals shown in the middle. The common mode noise is cancelled here, but the stochastic noise level has risen by a factor of √2, due to subtraction of two magnetometer signals building the gradiometer.

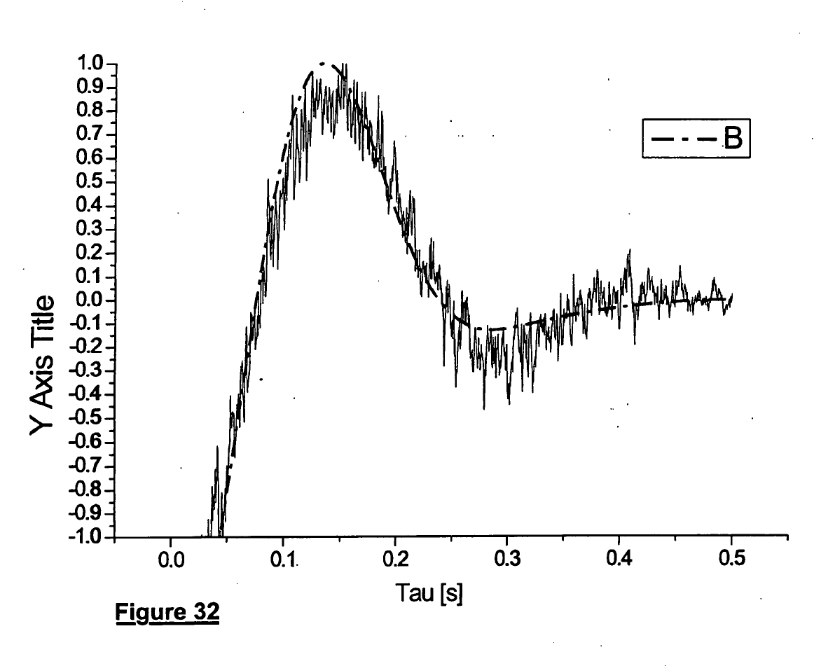

FIG. 32 shows the inverse auto correlation of the gradiometer signal. This correlation function sows an improvement in the signal-to-noise ratio over conventional gradiometry or magnetometry and would allow the detection of the simulated test dipole in the noise scenario shown in FIG. 31 by using, for example, a simple threshold around the point of the expected time delay. More sophisticate d methods other than a simple threshold, for example like shape recognition or local maxima detection may be used as well to identify a detection case. The dashed-dotted line in FIG. 32 shows the auto correlation function of the gradiometer built from two magnetometer signals for comparison.

Correlation functions do not carry phase information. Therefore we can use the correlation of the background, acquired prior or after an event measurement to reduce the influence of periodic noise, such as 50 Hz noise, vibrations and so on. In one simulation we added 50 Hz and 150 Hz interference signals to both magnetometer channels. Each interference signal has a different phase and amplitude with respect to the two channels. A gradiometer can not reduce those phase shifted signals efficiently. Because correlation functions do not carry phase information we can use the correlation of the background noise, acquired prior or after an event measurement to reduce the influence of periodic noise, such as 50 Hz interference, vibrations and so on. By subtracting the background correlation function from the event measurement correlation function we can significantly reduce periodic interference.

It is noted that, while the auto-cross correlation technique and background subtraction technique described in and with reference to equations 14 to 27 and FIGS. 20 to 25, 31 and 32 has been utilised in a system using two SQUID magnetometers to detect contaminants having a magnetic moment, the auto-cross-correlation technique may be applied in other applications. Such applications could include multi sensor applications in general, such as: telecommunications whether over a wireless, optical, or electrical medium; radar applications such as radar speed measurements, radar imaging, and weather radar; sound detection using 2 microphones; product inspection; security screening such as walk-through human screening; magnetic or gravity anomaly detection whether airborne or land based; biologically originating magnetic field sensing such as brain or liver scanning; surface acoustic wave using background measurement; or other applications where two (or more) copies of a signal of interest can be obtained having a time delay.

As discussed in the following with reference to FIGS. 26 to 29, large common mode noise signals overlap the correlation of an event and increase the difficulty of detecting the event. A further technique is applied in the system 100 to deal with such large external noise or unwanted signals recorded by the SQUIDs. FIG. 26 illustrates a circumstance in which a large background signal may be detected by the two SQUIDs: movement of a metal item 2600 (a chair) nearby the metal detector while measuring a quite small sample 160.

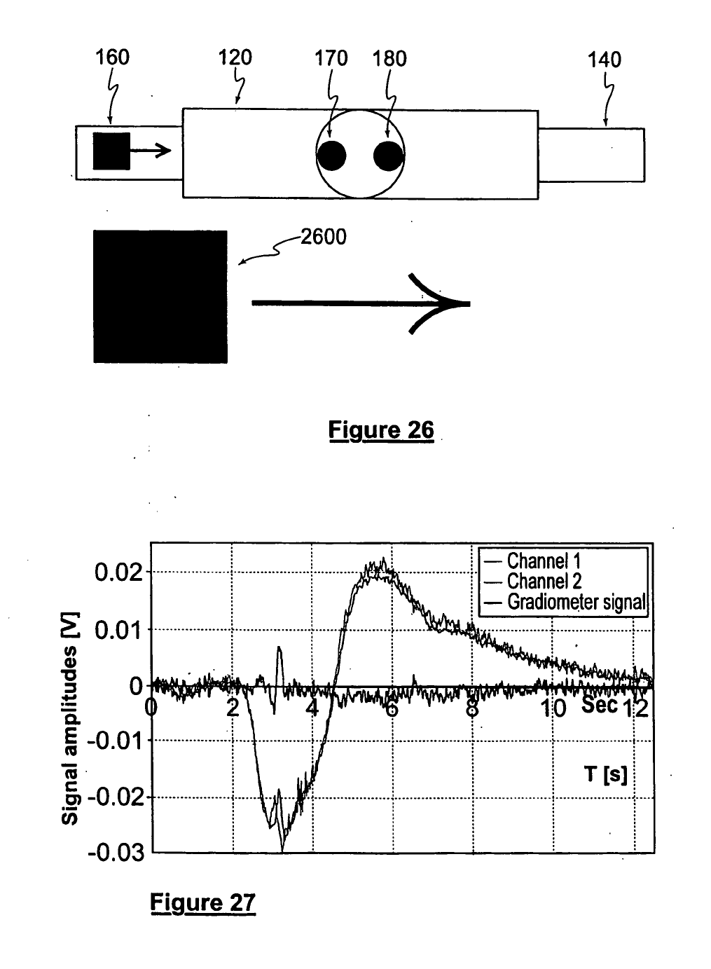

FIG. 27 illustrates the signal trace produced by each SQUID magnetometer 170, 180, together with the output of the gradiometer under the circumstance illustrated in FIG. 26, and illustrates the strength of the gradiometer in such a situation. The external noise source is a common mode signal and thus substantially eliminated by the gradiometer.

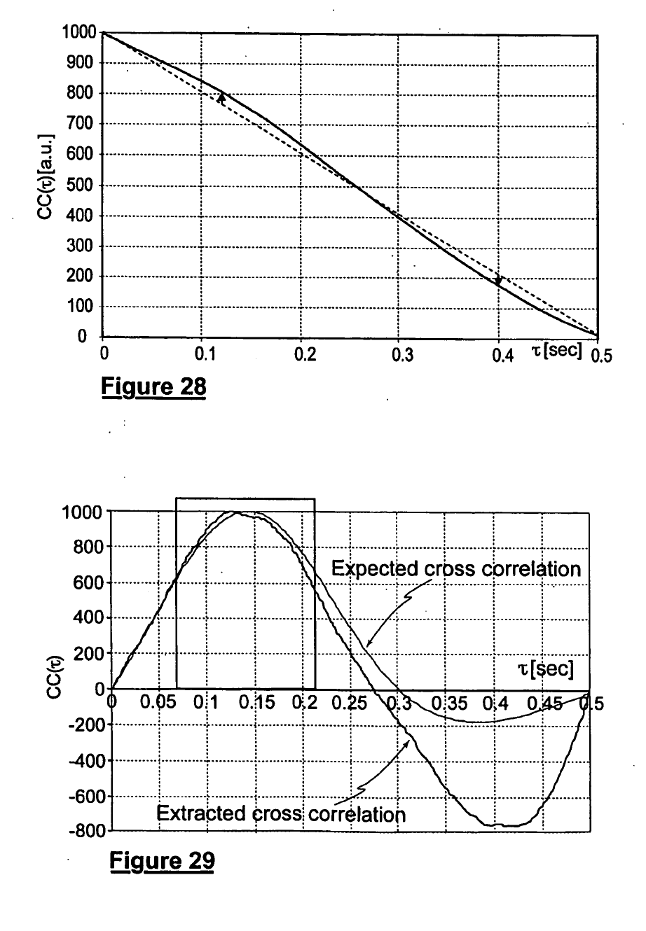

FIG. 28 illustrates the cross correlation of the SQUID magnetometers' output signals shown in FIG. 27. The large background signal has substantially corrupted the cross correlation such that it takes a shape substantially different to the expected cross correlation shapes shown in FIG. 16. However, by determining a linear fit (dotted line) for the cross correlation of FIG. 28 and subtracting this linear fit from the correlation itself (solid line), a more similar correlation shape is extracted. FIG. 29 compares the extracted cross correlation produced by this subtraction to an expected cross correlation shape.

While the extracted cross correlation still has some distortion due to the unknown shape of the cross correlation of the large nearby noise source, nevertheless the extracted cross correlation shape is similar to the expected cross correlation shape. It is noted that the extracted cross correlation diverges more from the expected cross correlation for larger values of; and the approximation is sufficient in the indicated areas around τₘₐₓ.

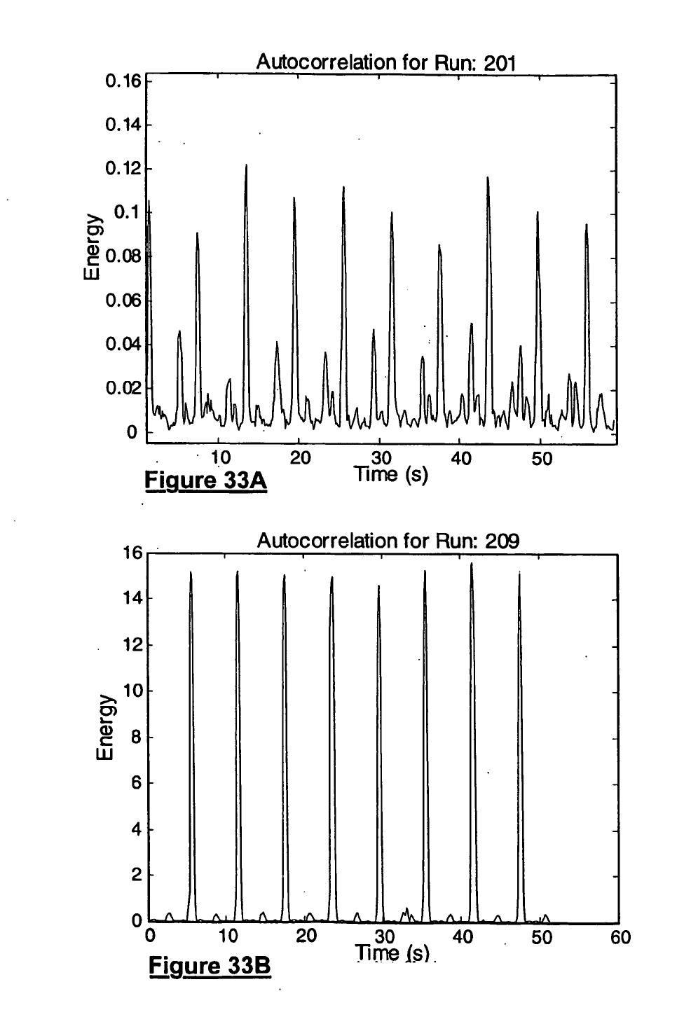

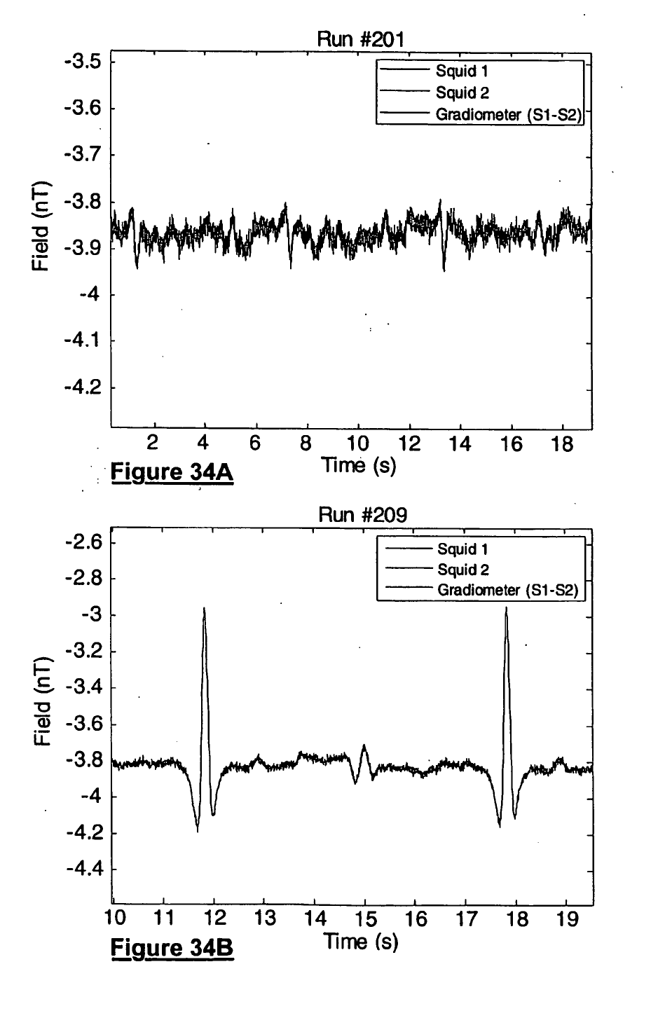

FIGS. 33 and 34 illustrate results of a further embodiment of the present invention. This embodiment arises from noting that the continuous calculation of the autocorrelation (at lag 0) of a band-pass filtered gradiometer signal generates a time-series estimate of the energy in the gradiometer signal. When compared to a contaminant-free signal's energy level (due to inherent noise and described statistically from training data), the estimated energy of the signal in the presence of a contaminant is considerably larger. This forms a viable threshold-based detector for the presence of these contaminants and is superior to a pure gradiometer ‘blip’ detector by up to a factor of 10.

The band-pass filtered gradiometer signal generated by a passing contaminant contains a complex waveform formed by the difference in the two magnetometer signals generated by the contaminant. A technique for identifying this waveform is autocorrelation (with lag 0) of the gradiometer signal. This technique, applied over successive periods of gradiometer data corresponding to the expected time of contact of a sample passing the two sensors (dependent on the velocity of the sample), effectively measures the energy in the signal over time.

Statistical properties of the energy of the gradiometer signal in the presence of noise only can be estimated from training data (captured in situ or otherwise) and used to derive a threshold detector for the autocorrelation output signal with a desired probability of false-alarm (false positive) or miss (false negative). Zero-biasing (subtracting the average from each period of data) is performed to remove any constant bias in the auto correlation calculation output.

The mean (μ) and standard deviation (σ) of the zero-biased autocorrelation signal in the absence of a contaminant can be used to determine a suitable detector threshold. This decision can be based on the desired minimum probability (assuming a normal distribution) of the detector recording a false alarm.

This technique is superior to simple rising/falling edge thresholds in the gradiometer signal, as it combines the information in the entire waveform (which is spread over multiple samples and can include negative components as well as positive components) and is a form of non-linear low-pass filtering.

FIGS. 33a and 33b illustrate the peak size of a noise-only correlation and a contaminant signal autocorrelation, respectively. FIGS. 34a and 34b illustrate the waveform of a noise-only signal and the waveform of a contaminant signal, respectively. The size of the peak of the contaminant autocorrelation is about 15, whereas the peaks due to noise only are about 0.13, a factor of 110 between them.

Compare this to waveform ‘blip’ detection based on the time-domain (waveform) gradiometer signal. The peak of the contaminant gradiometer signal is 0.8 V (above the ‘flat’ line preceding it), whereas peaks from the noise only gradiometer are about 0.05 V from an average ‘baseline’ (0.1 V peak-to-peak), a factor of only 8-16. Thus in a very rough sense, autocorrelation detection is about 7-13 times better than time-domain detection.

The autocorrelation signal formula is:

$${R}_{xx} [ t ] = {\sum }_{k = 0}^{N} {\vert x [ t - k ] \vert}^{2}$$

where x is the zero-biased gradiometer signal, and t represents an offset into the signal and is incremented to generate a ‘time’ series of autocorrelations of N data points. This can be thought of as moving a ‘processing window’ across the data. If t is incremented by 1 between autocorrelations, there are as many samples in the autocorrelation signal as the original gradiometer signal. Typically, t is incremented by ¼ or ½ of N for efficiency reasons, as it is sufficient that any given gradiometer signal generated by a contaminant be wholly contained with data block of N points. Appropriate selection of N and the increment on t is dependent on the velocity of the conveyor and the geometry of the sensor system. Band-pass filtering is preferably applied, for example by FIR filtering of signals from 1 Hz to 15 Hz, this band being dependent on the speed of the conveyor.

It will be appreciated by persons skilled in the art that numerous variations and/or modifications may be made to the invention as shown in the specific embodiments without departing from the spirit or scope of the invention as broadly described. For example, as the expected signal shape is mathematically known, with the parameters distance to sensor and magnetic moment of the sample, a wavelet can be defined out of this theoretical signal. To perform a wavelet transformation with this wavelet might be an alternative way to extract the information out of the noise signals. Notably, a simplification can be made because only certain parts of the wavelet transformation output are needed, which might make it possible to be processed in real time. This wavelet transformation could also be used with the gradiometer signal or even the cross correlation signal.

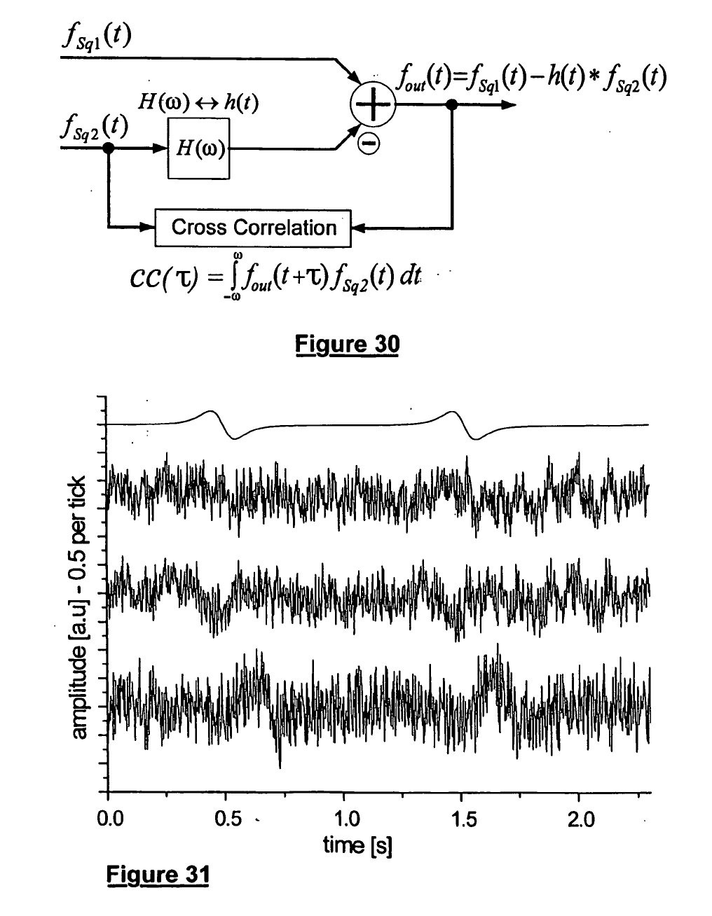

Another alternative approach may include adaptive filtering. This is based on the gradiometer technique. With the adaptive filtering method we can filter the reference signal and afterwards subtract it from the other channel. The basic system is the same as the gradiometer with regression in the frequency domain, but the way the filter coefficients are calculated is very different. With adaptive filtering, the goal is to change the filter constantly to always offer the best possible noise cancellations. Thus one configuration measurement of the environment noise is inadequate, and it becomes necessary to use another way to calculate the filter coefficients. Accordingly, such embodiments might perform a cross correlation between the output signal and the reference signal. If this function is zero, all noise acquired with the reference channel has been cancelled out. Thus, the goal is to minimize the cross correlation function to achieve maximum noise cancellation in adaptive filtering. One system for implementing adaptive filtering is shown in FIG. 30.

The present embodiments are, therefore, to be considered in all respects as illustrative and not restrictive.

1. A method of recovering a source signal in a noisy environment, comprising:
obtaining a first received signal (S1) and a second received signal (S2), S1 and S2 being time-spaced received versions of the source signal;
determining the cross-correlation (CC1) of S1 with S2;
determining the cross-correlation (CC2) of S2 with S1;
determining the autocorrelation (AC1) of S1;
determining the autocorrelation (AC2) of S2; and
calculating +/−(CC1+CC2−AC1−AC2).

2. The method of claim 1 further comprising obtaining S1 from a first sensor and obtaining S2 from a second sensor physically spaced from the first sensor, and wherein a time-spacing between S1 and S2 is effected by passing a subject producing a substantially constant source signal past the first and second sensors.

3. The method of claim 1 wherein the sensors are positioned at differing distances away from an origin of the source signal, such that the arrival time of the signal at each sensor is distinct, by an amount which depends on the speed of propagation of the signal.

4. The method of any one of claims 1 to 3 further comprising applying a scaling factor to compensate for differing strengths of S1 and S2 such as may be caused by attenuation of the signal between the two sensors, and/or differing sensitivities of the first and second sensors.

5. The method of any one of claims 1 to 4 wherein the time spacing between S1 and S2 arises by way of repeated transmission or generation of the source signal.

6. The method of any one of claims 1 to 5 further comprising:
at times at which no source signal is present, obtaining a first background signal (N1) from a first sensor and a second background signal (N2) from a second sensor spaced apart from the first sensor;
determining a background autocorrelation (BAC1) of N1;
determining a background autocorrelation (BAC2) of N2;
determining a background cross-correlation (BCC1) of N1 with N2;
determining a background cross-correlation (BCC2) of N2 with N1;
subtracting BAC1 and BAC2 from AC1 and AC2, respectively, to produce corrected auto correlations CAC1 and CAC2;
subtracting BCC1 and BCC2 from CC1 and CC2, respectively, to produce corrected cross correlations CCC1 and CCC2; and
calculating +/−(CCC1+CCC2−CAC1−CAC2).

7. The method of any one of claims 1 to 6, further comprising applying linear regression in the time or frequency domain in order to determine coefficients which take into account mismatches between the first and second signals, such that noise in S1 and S2 is balanced by the coefficients before the auto-cross-correlation is calculated.

8. A device for recovering a source signal in a noisy environment, comprising:
at least one sensor for obtaining a first received signal (S1) and a second received signal (S2), S1 and S2 being time-spaced received versions of the source signal; and
a processor for determining the cross-correlation (CC1) of S1 with S2, for determining the cross-correlation (CC2) of S2 with S1; for determining the autocorrelation (AC1) of S1; for determining the autocorrelation (AC2) of S2; and for calculating +/−(CC1+CC2−AC1−AC2).

9. A computer program for recovering a source signal in a noisy environment, comprising:
code for obtaining a first received signal (S1) and a second received signal (S2), S1 and S2 being time-spaced received versions of the source signal;
code for determining the cross-correlation (CC1) of S1 with S2;
code for determining the cross-correlation (CC2) of S2 with S1;
code for determining the autocorrelation (AC1) of S1;
code for determining the autocorrelation (AC2) of S2; and
code for calculating +/−(CC1+CC2−AC1−AC2).

10. A system for detecting a magnetic contaminant in a product, the system comprising:
a magnetic shield casing;
means for transporting the product within the casing;
a magnetic sensing device within and shielded by the casing, configured to sense the magnetic moment of a passing magnetic contaminant at spaced apart times to produce a first sensed signal and a second sensed signal; and
a processor for determining from the first sensed signal and the second sensed signal whether a magnetic contaminant has been detected.

11. The system of claim 10 wherein the processor is adapted to process the first sensed signal and the second sensed signal in accordance with the method of any one of claims 1 to 7.

12. The system of claim 10 or claim 11, wherein the magnetic sensing device comprises two separate sensors separated by a baseline distance and positioned proximal to and along a path of travel defined by the transport means such that a velocity of products transported within the casing determines the time spacing between the time at which the first sensed signal is obtained and the time at which the second sensed signal is obtained.

13. The system of claim 12 wherein a length of the path of travel through the magnetic casing is sufficiently longer than the baseline distance that noise and signal sources external of the magnetic casing are recorded by the two sensors at substantially the same time.

14. The system of any one of claims 10 to 13 wherein the processor is configured to combine the first sensed signal and second sensed signal in a gradiometer configuration to improve a signal to noise ratio.

15. The system of claim 14 comprising a control means for controlling a velocity at which the product is transported within the casing, configured to control an expected time of a minima in the first sensed signal to coincide with an expected time of a maxima in the second sensed signal so as to maximise the gradiometric output at that time.

16. The system of claim 14 or claim 15 wherein the magnetic sensing device comprises first and second magnetic sensors spaced apart by a distance chosen to maximise a gradiometric output by coinciding a minima in the first sensed signal of the first sensor with a maxima in the second sensed signal of the second sensor.

17. The system of any one of claims 14 to 16 wherein the processor is configured to apply regression in at least one of the time domain and the frequency domain in order to account for differing sensitivities or responses of the or each sensor used to obtain the first and second sensed signals.

18. The system of any one of claims 10 to 17 further comprising a pre-magnetization device to pre-magnetize products to be transported within the casing.

19. The system of claim 18 wherein the pre-magnetization device is configured to align a magnetization of products with a maximum sensitivity axis of the or each sensing device.

20. The system of any one of claims 10 to 19 wherein the or each sensing device comprises at least one of a SQUID magnetometer and a SQUID gradiometer.

21. The system of any one of claims 10 to 20 wherein the magnetic sensing device is sensitive to magnetic fields along a z-axis substantially perpendicular to the path of travel, and is sensitive to magnetic fields along a y-axis substantially perpendicular to the path of travel and substantially perpendicular to the x-axis.

22. The system of claim 21 wherein the sensing device comprises:
a first sensor pair sensitive to the z-axis and separated by a baseline distance and positioned proximal to and along a path of travel; and
a second sensor pair sensitive to the y-axis and separated by a baseline distance and positioned proximal to and along a path of travel; and

23. The system of claim 21 wherein the sensing device comprises a single sensor pair separated by a baseline distance and positioned proximal to and along a path of travel, wherein each sensor of the sensor pair is sensitive to magnetic fields of differing orientation including fields along the y-axis and fields along the z-axis.

24. The system of any one of claims 10 to 23 further comprising a means to determine when a product is passing the sensors.

25. The system of any one of claims 10 to 24 wherein the transport means comprises a non-magnetic conveyor belt driven by a motor external to the magnetic casing.

26. The system of any one of claims 10 to 25 wherein the processor is configured to determine a cross-correlation of an expected sensed signal profile with at least one of the first and second sensed signals.

27. The system of claim 26 further comprising a memory device storing a plurality of expected sensed signal profiles differing in a manner corresponding to factors such as varying dipole orientation, varying position of the contaminant laterally of the path of travel, contaminant distance from the sensor, and contaminant size, allowing qualitative information regarding such factors to be derived by, cross-correlation of each such expected sensed signal profile with at least one of the first and second sensed signals.

28. The system of any one of claims 10 to 27 wherein the processor is configured to determine a cross-correlation of an expected cross-correlation profile with the cross-correlation of the first and second sensed signals.

29. The system of claim 28 further comprising a memory device storing a plurality of expected cross-correlation profiles differing in a manner corresponding to factors such as varying dipole orientation, varying position of the contaminant laterally of the path of travel, contaminant distance from the sensor, and contaminant size, allowing qualitative information regarding such factors to be derived by cross-correlation of each such expected cross-correlation profile with the cross-correlation of the first and second sensed signals.

30. The system of any one of claims 10 to 29 further comprising at least one filter configured to filter the first and second sensed signals in order to retain signal components in a frequency band of interest, while attenuating signal components in other frequency bands.

31. A method for detecting a magnetic contaminant in a product, the method comprising:
transporting the product past a magnetic sensing device;
obtaining a first sensed signal and a second sensed signal as the product passes the magnetic sensing device, the first sensed signal and the second sensed signal being time-spaced received versions of the source signal produced by the product; and
determining from the first sensed signal and the second sensed signal whether a magnetic contaminant has been detected.

32. A computer program for detecting a magnetic contaminant in a product, the method comprising:
code for obtaining a first sensed signal and a second sensed signal as the product is transported past a magnetic sensing device, the first sensed signal and the second sensed signal being time-spaced received versions of the source signal produced by the product; and
code for determining from the first sensed signal and the second sensed signal whether a magnetic contaminant has been detected.
